(19) United States
(12) Patent Application Publication
(10) Pub. No.: US 2021/0327930 A1
(43) Pub. Date: Oct. 21, 2021

(54) IMAGE SENSOR AND METHOD FOR FABRICATING THE SAME

(71) Applicant: SAMSUNG ELECTRONICS CO., LTD., Suwon-si (KR)

(72) Inventors: KangMook LIM, Seoul (KR); Yeo Seon CHOI, Seoul (KR); Sung In KIM, Hwaseong-si (KR); Chang Hwa KIM, Hwaseong-si (KR)

(21) Appl. No.: 17/128,362

(22) Filed: Dec. 21, 2020

(30) Foreign Application Priority Data
Apr. 21, 2020 (KR) 10-2020-0047902

(51) Int. Cl. H01L 27/146

(52) U.S. Cl. CPC H01L 27/1463; H01L 27/14645; H01L 27/14621; H01L 27/14689; H01L 27/14636; H01L 27/1464; H01L 27/14627

(57) ABSTRACT

An image sensor includes a substrate which includes a plurality of unit pixels. Each of the plurality of unit pixels includes a photoelectric conversion layer. A pixel separation pattern is disposed in the substrate and has a and shape that includes a plurality of grid points. The pixel separation pattern is configured to separate each of the plurality of unit pixels from each other. A support structure is disposed in the substrate and is positioned to correspond to the plurality of grid points of the pixel separation pattern. The support structure is configured to support adjacent unit pixels of the plurality of unit pixels.

### CROSS-REFERENCE TO RELATED APPLICATION

This application claims priority under 35 U.S.C. §119 to Korean Patent Application No. 10-2020-0047902, filed on Apr. 21, 2020 in the Korean Intellectual Property Office, the disclosure of which is incorporated herein by reference in its entirety.

### TECHNICAL FIELD

The present inventive concepts relate to an image sensor and a method for fabricating the same. More specifically, the present inventive concepts relate to an image sensor including a pixel separation pattern and a method for fabricating the same.

### DISCUSSION OF RELATED ART

An image sensor is a semiconductor device that converts optical information into electric signals, Examples of an image sensor include a charge coupled device (CCD) image sensor and a complementary metal-oxide semiconductor (CMOS) image sensor.

The image sensor may be formed in the form of a package. The package protects the image sensor, and may have a configuration that permits light to enter a photo receiving surface or a sensing region of the image sensor.

Recently, a backside illumination (BSI) image sensor in which incident light is radiated through a backside of the semiconductor substrate so that pixels formed in the image sensor have improved photo receiving efficiency and photosensitivity is in development.

### SUMMARY

Aspects of the present inventive concepts provide an image sensor having increased product reliability and quality.

Aspects of the present inventive concepts also provide a method for fabricating an image sensor that has increased product reliability.

However, aspects of the present inventive concepts are not limited to those set forth herein. The above and other aspects of the present inventive concepts will become more apparent to one of ordinary skill in the art to which the present inventive concepts pertain by referencing the detailed explanation of exemplary embodiments given below.

According to an exemplary embodiment of the present inventive concepts, an image sensor includes a substrate which includes a plurality of unit pixels. Each of the plurality of unit pixels includes a photoelectric conversion layer. A pixel separation pattern is disposed in the substrate and has a grid shape that includes a plurality of grid points. The pixel separation pattern is configured to separate each of the plurality of unit pixels from each other. A support structure is disposed in the substrate and is positioned to correspond to the plurality of grid points of the pixel separation pattern. The support structure is configured to support adjacent unit pixels of the plurality of unit pixels.

According to another exemplary embodiment of the present inventive concepts, an image sensor includes a substrate that includes a first pixel, a second pixel adjacent to the first pixel in a first direction, and a third pixel adjacent to the first pixel in a second direction intersecting the first direction. A pixel separation pattern is disposed in the substrate and is configured to separate the first to third pixels from each other. A support structure is disposed in the substrate between the second pixel and the third pixel and is configured to connect the first to third pixels to each other.

According to another exemplary embodiment of the present inventive concepts, an image sensor includes a first substrate which includes a first surface that is configured to receive incident light, and a second surface that is opposite to the first surface. A plurality of unit pixels is disposed in the first substrate. Each of the plurality of unit pixels includes a photoelectric conversion layer. A pixel separation pattern is disposed in the first substrate and has a grid shape that includes a plurality of grid points. The pixel separation pattern is configured to separate each of the plurality of unit pixels from each other. A support structure is disposed in the first substrate. The support structure surrounds the plurality of grid points of the pixel separation pattern. A color filter is disposed on the first surface of the first substrate and is positioned to correspond to each unit pixel of the plurality of unit pixels. A microlens is disposed on each of the color filters. A first wiring structure is disposed on the second surface of the first substrate. The first wiring structure includes a first inter-wiring insulation film and a first wiring disposed in the first inter-wiring insulation film.

### BRIEF DESCRIPTION OF THE DRAWINGS

These and/or other aspects will become apparent and more readily appreciated from the following detailed description of exemplary embodiments, taken in conjunction with the accompanying drawings in which:

FIG. 1 is a block diagram of an image sensor according to an exemplary embodiment of the present inventive concepts.

FIG. 2 is a circuit diagram of a unit pixel of an image sensor according to an exemplary embodiment of the present inventive concepts.

FIG. 3 is a layout diagram of an image sensor according to an exemplary embodiment of the present inventive concepts.

FIG. 4 is a cross-sectional view of an image sensor taken along a line A-A of FIG. 3 according to an exemplary embodiment of the present inventive concepts.

FIG. 5 is a cross-sectional view of an image sensor taken along lines B-B, C-C and D-D of FIG. 3 according to an exemplary embodiment of the present inventive concepts.

FIG. 6 is a layout diagram of the image sensor according to a comparative embodiment.

FIG. 7 is a cross-sectional view of an image sensor according to an exemplary embodiment of the present inventive concepts.

FIG. 8 is a cross-sectional view of an image sensor taken along lines SC1-SC1 and SC2-SC2 of FIG. 7 according to an exemplary embodiment of the present inventive concepts.

FIG. 9 is a cross-sectional view of an image sensor according to an exemplary embodiment of the present inventive concepts

FIG. 10 is a cross-sectional view of an image sensor taken along lines SC1-SC1 and SC2-SC2 of FIG. 9 according to an exemplary embodiment of the present inventive concepts.

FIG. 11 is a cross-sectional view of an image sensor according to an exemplary embodiment of the present inventive concepts.

FIG. 12 is a cross-sectional view of an image sensor taken along lines SC1-SC1 and SC2-SC2 of FIG. 9 according to an exemplary embodiment of the present inventive concepts

FIG. 13 is a cross-sectional view of an image sensor according to an exemplary embodiment of the present inventive concepts.

FIG. 14 is a layout diagram of an image sensor according to an exemplary embodiment of the present inventive concepts.

FIG. 15 is a cross-sectional view of the image sensor of FIG. 14 according to an exemplary embodiment of the present inventive concepts.

FIG. 16 is a cross-sectional view of an image sensor according to an exemplary embodiment of the present inventive concepts.

FIGS. 17 to 30 are intermediate stage diagrams of a method for fabricating an image sensor according to exemplary embodiments of the present inventive concepts.

### DETAILED DESCRIPTION OF EXEMPLARY EMBODIMENTS

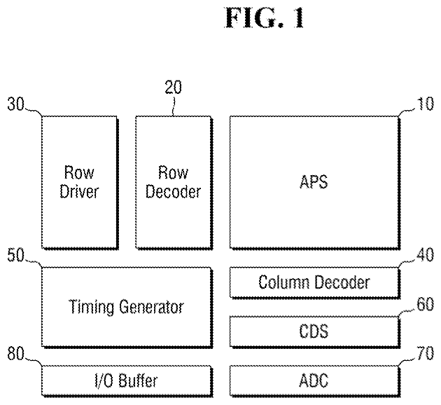

Hereinafter, an image sensor according to exemplary embodiments of the present inventive concepts will be described with reference to FIGS. 1 to 16.

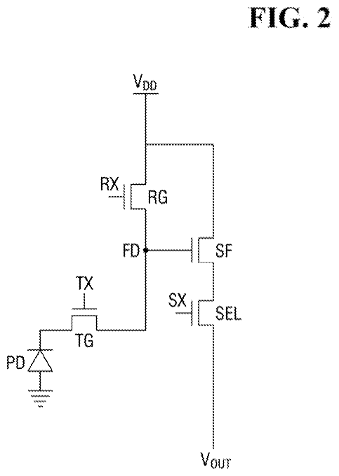

FIG. 1 is an exemplary block diagram for explaining an image sensor according to an exemplary embodiment of the present inventive concepts. FIG. 2 is an exemplary circuit diagram for explaining a unit pixel of an image sensor according to a exemplary embodiment of the present inventive concepts.

Referring to FIG. 1, the image sensor according to an exemplary embodiment of the present inventive concepts includes an active pixel sensor array (APS) 10, a row decoder 20, a row driver 30, a column decoder 40, a timing generator 50, a correlated double sampler (CDS) 60, an analog-to-digital converter (ADC) 70, and input/output buffer (I/O Buffer) 80.

In an exemplary embodiment, the active pixel sensor array 10 includes a plurality of unit pixels arranged two-dimensionally and may convert an optical signal into an electric signal. The active pixel sensor array 10 may be driven by a plurality of driving signals, such as a pixel selection signal, a reset signal and a charge transfer signal, received from the row driver 30. The electric signal convened by the active pixel sensor array 10 may be provided to the correlated double sampler 60.

The row driver 30 may provide a plurality of driving signals for driving a plurality of unit pixels to the active pixel sensor array 10 in accordance with the result decoded by the row decoder 20. In an exemplary embodiment in which the unit pixels are arranged in the form of a matrix, a driving signal may be provided for each row.

The timing generator 50 may provide timing and control signals to the row decoder 20 and the column decoder 40.

The correlated double sampler (CDS) 60 may receive, hold and sample the electric signals generated by the active pixel sensor array 10. The correlated double sampler 60 may doubly sample a specific noise level and a signal level due to the electric signal, and may output a difference level corresponding to a difference between the noise level and the signal level.

The analog-to-digital converter (ADC) 70 may convert an analog signal corresponding to the difference level output from the correlated double sampler 60 into a digital signal and may output the digital signal.

The input/output buffer 80 latches the digital signal, and the latched signal may sequentially output the digital signal to an image signal processing unit in accordance with the decoding result from the column decoder 40.

Referring to the exemplary embodiment of FIG. 2, each unit pixel may include a photoelectric conversion layer PD, a transfer transistor TG, a floating diffusion region FD, a reset transistor RG, a source follower transistor SF, and a selection transistor SEL.

The photoelectric conversion layer PD may generate charges in proportion to an amount of light incident from the outside. The photoelectric conversion layer PD may be coupled with the transfer transistor TG that transfers the generated and accumulated charges to the floating diffusion region FD. The floating diffusion region FD is a region which converts charges into voltage and has a parasitic capacitance. Therefore, charges may be accumulated and stored in the floating diffusion region FD.

One end of the transfer transistor TG may be connected to the photoelectric conversion layer PD, and the other end of the transfer transistor TG may be connected to the floating diffusion region FD. The transfer transistor TG may be formed of a transistor driven by a predetermined bias (e.g., a transfer signal TX). For example, the transfer transistor TG may transfer the charges generated from the photoelectric conversion layer PD to the floating diffusion region FD in accordance: with the transfer signal TX.

The source follower transistor SF may amplify a change in electric potential of the floating diffusion region FD to which electric charges are transferred from the photoelectric conversion layer PD, and may output the amplified changes in electrical potential of the floating diffusion region FID to an output line V_{OUT}. When the source follower transistor SF is turned on, a predetermined electric potential provided to the drain of the source follower transistor SF, such as a power supply voltage V_{DD}, may be transferred to a drain region of the selection transistor SEL.

The selection transistor SEL may select a unit pixel to be read in a row unit. In an exemplary embodiment, the selection transistor SEL may be made up of a transistor driven by a selection line that applies a predetermined bias (e.g., a row selection signal SX).

The reset transistor RG may periodically reset the floating diffusion region ED. The reset transistor RG may be made up of a transistor driven by a reset line that applies a predetermined bias (e.g., a reset signal RX). When the reset transistor RG is turned on by the reset signal RX, a predetermined electric potential provided to the drain of the reset: transistor RG, such as the power supply voltage V_{DD}, may be transferred to the floating diffusion region FD.

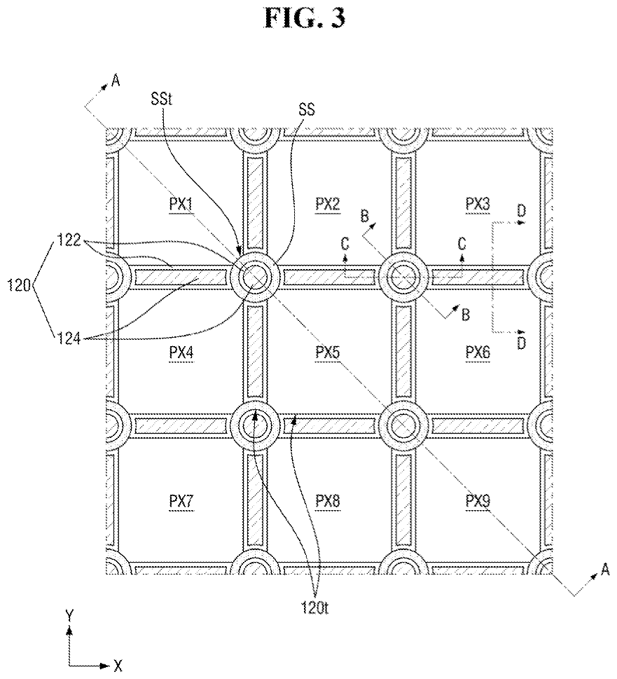

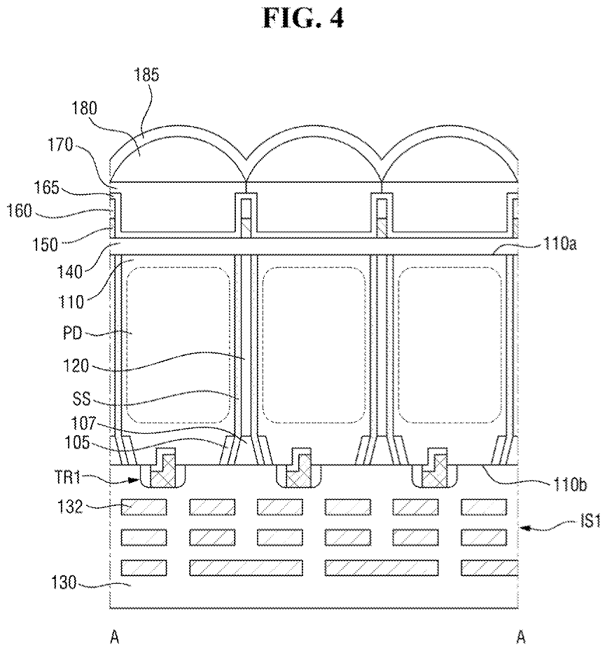

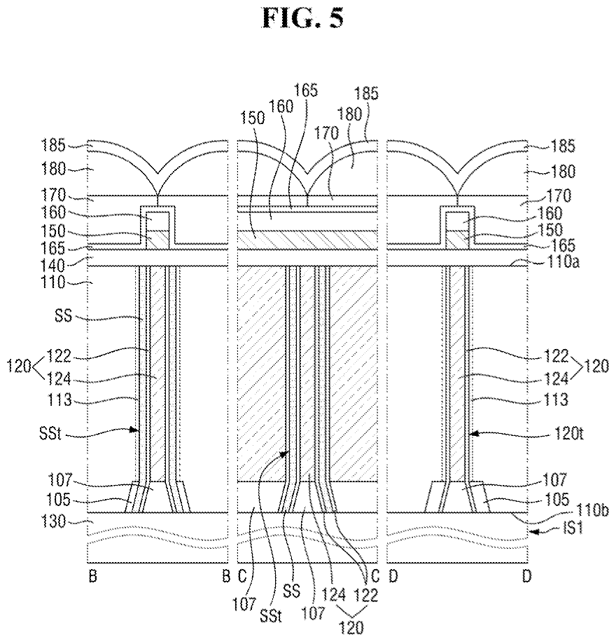

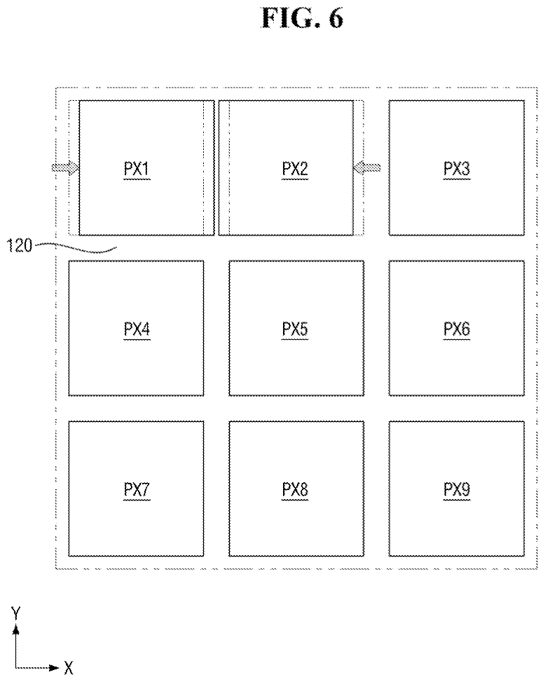

FIG. 3 is a layout diagram for explaining an image sensor according to an exemplary embodiment of the present inventive concepts. FIG. 4 is a cross-sectional view taken along a line A-A of FIG. 3. FIG. 5 is a cross-sectional view taken along lines B-B, C-C and D-D of FIG. 3. FIG. 6 is a layout diagram for explaining effects of the image sensor according to an exemplary embodiment of the present inventive concepts. For convenience of explanation, substantially identical elements that were explained above with respect to FIGS. 1 and 2 will be briefly described or omitted.

Referring to FIGS. 3 to 5, an image sensor according to an exemplary embodiment of the present inventive concepts may include a first substrate 110, a first element separation pattern 105, a pixel separation pattern 120, and a support structure SS, a first wiring structure IS1, a surface insulation film 140, a color filter 170 and a microlens 180.

In an exemplary embodiment, the first substrate 110 may be a semiconductor substrate. For example, the first substrate 110 may be bulk silicon or SOI (silicon-on-insulator). The first substrate 110 may be a silicon substrate or may include other materials, such as at least one compound selected from silicon germanium, indium antimonide, lead telluride, iridium arsenide, indium phosphide, gallium arsenide and gallium antimonide. Alternatively, the first substrate 110 may have an epitaxial layer formed on a base substrate.

The first substrate 110 may include a first surface 110a and a second surface 110b that are opposite to each other e.g., in a thickness direction of the first substrate 110). In exemplary embodiments to be described below, the first surface 110a may be referred to as a back side of the first substrate 110, and the second surface 110b may be referred to as a front side of the first substrate 110. In an exemplary embodiment, the first surface 110a of the first substrate 110 may be a photo receiving surface on which light is incident. The first surface 110a may be configured to receive incident light. For example, the image sensor according to an exemplary embodiment of the present inventive concepts may be a backside illumination (BSI) image sensor.

A plurality of unit pixels including first to ninth unit, pixels PX1 to PX9 may be formed on the first substrate 110. For example, as shown in the exemplary embodiment of FIG. 3, the first to ninth unit pixels PX1 to PX9 of the plurality of unit pixels may be arranged two-dimensionally (e.g., in the form of matrix) in a plane including a first direction X and a second direction Y In an exemplary embodiment, the first and second directions X, Y may be perpendicular to each other. While the exemplary embodiment of FIG. 3 includes first to ninth unit pixels PX1 to PX9, in other exemplary embodiments the plurality of unit pixels may include various different numbers of unit pixels.

Each of the first to ninth unit pixels PX1 to PX9 may include the photoelectric conversion layer PD. The photoelectric conversion layer PD may be formed in the first substrate 110. For example, the photoelectric conversion layer PD may be formed between the first surface 110a and the second surface 110b of the first substrate 110 The photoelectric conversion layer PD may generate charges in proportion to an amount of light incident from the outside.

In an exemplary embodiment, the photoelectric conversion layer PD may be formed by doping impurities in the first substrate 110. For example, the photoelectric conversion layer PD may be formed by ion-implantation of n-type impurities into the p-type first substrate 110, in an exemplary embodiment, the photoelectric conversion layer PD may have a potential gradient in a vertical direction (e.g., a direction intersecting the first surlier 110a and the second surface 110b of the first substrate 110) perpendicular to an upper surface of the first substrate 110 which may be a thickness direction of the first substrate 110. For example, the photoelectric conversion layer PD may have a form in which a plurality of impurity regions are stacked.

In an exemplary embodiment, the photoelectric conversion layer PD may include at least one element selected from a photo diode, a photo transistor, a photo gate, a pinned photo diode, an organic photo diode, a quantum dot and a combination thereof However, exemplary embodiments of the present inventive concepts are not limited thereto.

Each of the first to ninth unit pixels PX1 to PX9 of the plurality of unit pixels may include a first electronic element TR1. As shown in the exemplary embodiment of FIG. 4, the first electronic element TR1 may be disposed on the second surface 110b of the first substrate 110. However, exemplary embodiments of the present inventive concepts are not limited thereto. The first electronic element TR1 may be connected to the photoelectric conversion layer PD to form various transistors for processing electric signals. For example, the first electronic element TR1 may form transistors such as the transfer transistor TG, the reset transistor RG, the source follower transistor SF, the selection transistor SEL or the like described above in the unit pixel shown in the exemplary embodiment of FIG. 2.

In an exemplary embodiment, the first electronic element TR1 may include a vertical transfer transistor. For example, a part of the first electronic element TR1 forming the above-described transfer transistor TG may extend into the first substrate 110. Since such a transfer transistor TG may reduce the region of the unit pixel, the transfer transistor TG enables high integration of the image sensor.

The first element separation pattern 105 may be formed in the first substrate 110. The first element separation pattern 105 may be formed, for example, by embedding an insulating material in a shallow trench formed by patterning the first substrate 110. In some embodiments, the first element separation pattern 105 may extend from the second surface 110b of the first substrate 110.

The first element separation pattern 105 may define an active region of each of the first to ninth unit pixels PX1 to PX9 of the plurality of unit pixels, For example, the first element separation pattern 105 may separate the transistors such as the transfer transistor TG, the reset transistor RG, the source follower transistor SF or the selection transistor SEL described above in the unit pixel shown in the exemplary embodiment of FIG. 2.

In an exemplary embodiment, the first element separation pattern 105 may include at least one compound selected from silicon oxide, silicon nitride, silicon oxynitride, aluminum oxide, tantalum oxide, and a combination thereof.

The pixel separation pattern 120 may be disposed in the first substrate 110. In an exemplary embodiment, the pixel separation pattern 120 may be formed by embedding an insulating material in a deep trench (e.g., the pixel separation trench 120t of FIG. 5) formed by patterning the first substrate 110.

The pixel separation pattern 120 may define a plurality of unit pixels such as the first to ninth unit pixels PX1 to PX9. For example, as shown in the exemplary embodiment of FIG. 3, the pixel separation pattern 120 may be formed in a grid shape in a plan view (e.g., in a plane defined in the first direction X and second direction Y) to separate the plurality of unit pixels, such as the first to ninth unit pixels PX1 to PX9 from each other. For example, the pixel separation pattern 120 may be formed to surround each of the unit pixels PX1 to PX9 in a plan view (e.g., in a plane defined in the first direction X and second direction Y). As shown in the exemplary embodiment of FIG. 3, the grid shape of the pixel separation pattern 120 may include first portions that extend in the second direction Y, second portions that extend in the first direction X and a plurality grid points positioned where the respective first and second portions cross each other.

As shown in the exemplary embodiment of FIG. 3, the pixel separation pattern 120 may include a spacer film 122 and a filling film 124. For example, as shown in the exemplary embodiment of FIG. 5, a pixel separation trench 120t may be formed in a grid shape in a plan view (e.g., in a plane defined in the first direction X and second direction Y) in the first substrate 110 to separate the plurality of unit pixels, such as the first ninth unit pixels PX1 to PX9 from each other. The spacer film 122 may be disposed to conformally extend along the side surfaces of the pixel separation trench 120t. The filling film 124 may be disposed on the spacer film 122 to fill at least a partial portion of the pixel separation trench 120t.

In an exemplary embodiment, the spacer film 122 may include an oxide that has a lower refractive index than the first substrate 110. For example the spacer film 122 may include, at least one compound selected from silicon oxide, aluminum oxide and tantalum oxide. However, exemplary embodiments of the present inventive concepts are not limited thereto. The spacer film 122 having a lower refractive index than the first substrate 110 may refract or reflect light obliquely incident on the photoelectric conversion layer PD. In addition, the spacer film 122 may prevent photocharges generated in a specific unit pixel by the incident light from moving to an adjacent unit pixel (e.g. adjacent in the X or Y direction) due to a random drift. For example, the spacer film 1.22 may improve the photo receiving, rate of the photoelectric conversion layer PD to improve the quality of the image sensor according to some embodiments.

In an exemplary embodiment, the filling film 124 may include a conductive material, For example, the filling film 124 may include polysilicon poly (Si). However, exemplary embodiments of the present inventive concepts are not limited thereto. In an exemplary embodiment, a ground voltage or a negative voltage ma be applied to the filling film 124 including a conductive material. In this exemplary embodiment, an ESD (electrostatic discharge) bruise defect of the image sensor may be effectively prevented. Here, the ESD bruise defect refers to a phenomenon in which electric charges generated by ESD or the like is accumulated on the surface of the substrate (e.g., the first surface 110a) to generate stains such as a bruise on an image to be generated.

In an exemplary embodiment, the pixel separation pattern 120 may penetrate the first element separation pattern 105. For example, the pixel separation pattern 120 may extend from the second surface 110b in the first element separation pattern 105 and may penetrate entirely through the first element separation pattern 105. In an exemplary embodiment, the pixel separation pattern 120 may overlap the first element separation pattern 105 in a vertical direction perpendicular to the upper surface of the first substrate 110.

In an exemplary embodiment, the filling film 124 may not extend to the second surface 110b of the first substrate 110. For example, as shown in the exemplary embodiment of FIG. 5, the lower surface of the filling film 124 may be spaced apart from the second surface 110b of the first substrate 110 and may be positioned above the second surface 110b in the vertical direction of the first substrate 110.

In an exemplary embodiment, a capping pattern 107 may be disposed in the pixel separation pattern 120. The capping, pattern 107 may be interposed between the filling film 124 and a first wiring structure IS1 (e.g., in the vertical direction of the first substrate 110). In an exemplary embodiment, the capping pattern 107 may be formed by embedding the insulating material in a trench formed by recess of the filling film 124 of the pixel separation pattern 120.

in the exemplary embodiment of FIG. 5, on the basis of the second surface 110b of the first substrate 110, a depth of the capping pattern 107 is shown as being only the same as a depth of the first element separation pattern 105. However, exemplary embodiments of the present inventive concepts are not limited thereto. For example, in other exemplary embodiments, on the basis of the second surface 110b of the first substrate 110, the depth of the capping pattern 107 may be shallower or deeper than the depth of the first element separation pattern 105. For example, in some exemplary embodiments, a bottom surface of the capping pattern 107 may be disposed above or below a bottom surface of the first element separation pattern 105.

A support structure SS may be disposed in the first substrate 110. The support structure SS may be positioned to correspond to the grid points of the pixel separation pattern 120 in a plan view (e.g., in a plane defined in the first direction X and second direction Y). For example, as shown in the exemplary embodiment of FIG. 3, a support trench SSt may be disposed in a region corresponding to the grid point of the pixel separation pattern 120. The support structure SS may be formed in the support trench SSt. In an exemplary embodiment, the support structure SS may be conformally formed along the side surfaces of the support trench SSt.

The support structure SS may support the adjacent unit pixels of the plurality of pixels, such as the first to ninth pixels PX1 to PX9. For example, the side surface of the support structure SS may be in direct contact with the side surfaces of the plurality of unit pixels, such as the first to ninth pixels PX1 to PX9. As an example, as shown in FIG. 3, the support structure SS may be interposed between the first, second, fourth and fifth pixels PX1, PX2, PX4 and PX5. The outer surface of the support structure SS may be in direct contact with partial portions of the side surfaces of the first, second, fourth and fifth pixels PX1, PX2, PX4 and PX5. Accordingly, the first, second, fourth and fifth pixels PX1, PX2, PX4 and PX5 may be connected and supported by the support structure SS.

A partial portion of the side surface of the support structure SS that is not in direct contact with the side surfaces of the plurality of unit pixels, such, as the first to ninth unit pixels PX1 to PX9 may be in direct contact with the side surface of the pixel separation pattern 120. For example, the spacer film 122 of the pixel separation pattern 120 may conformally extend along the partial portion of the outer surface of the support structure SS that is not in direct contact with the side surfaces of the unit pixels, such as the first to ninth unit pixels PX1 to PX9.

In an exemplary embodiment, a partial portion of the pixel separation pattern 120 may be formed in the support structure SS. For example, a partial portion of the pixel separation trench 120t may be formed in the support structure SS. A partial portion of the pixel separation pattern 120 may fill the pixel separation trench 1201 in the support structure SS. In an exemplary embodiment, the spacer film 122 may conformally extend along the inner surface of the support structure SS, and the filling film 124 may fill the pixel separation trench 120t in the support structure SS. Accordingly, the spacer film 122 may be interposed between the support structure SS and the filling film 124. In addition, the spacer film 122 may not be interposed between the support structure SS and each of the plurality of unit pixels, such as the first to ninth unit pixels PX1 to PX9.

Since the support structure SS may be positioned to correspond to the grid points of the pixel separation pattern 120, the pixel separation pattern 120 disposed in the support structure SS may correspond to the grid points of the pixel separation pattern 120. Therefore, the support structure SS may surround the grid points of the pixel separation pattern 120 from a plan view (e.g., in a plane defined in the first direction X and second direction Y).

In an exemplary embodiment, the support structure SS may be exposed from the first surface 110a of the first substrate 110. For example, the support structure SS may extend from the first surface 110a of the first substrate 110 toward the second surface 110b of the first substrate 110. In an exemplary embodiments, the support structure SS may extend from the first surface 110a of the first substrate 110 to the second surface 110b of the first substrate 110 (e.g., in a vertical direction of the first substrate 110).

In an exemplary embodiment, the support structure SS may have a cylindrical shape with an axis extending in a vertical direction perpendicular to the upper surface of the first substrate 110. Although the support structure SS is shown as only having a cylindrical shape, exemplary embodiments of the present inventive concepts are not limited thereto. For example, in other exemplary embodiments, the support structure SS may have various different shapes including an oval cylindrical shape, and various polygonal cylindrical shapes such as a square cylindrical shape, etc.

In an exemplary embodiment, the support structure SS may penetrate the first element separation pattern 105. For example, the support structure SS may fully penetrate the first element separation pattern 105 and extend from the second surface 110b through the first element separation pattern 105. In an exemplary embodiment, the support structure SS may overlap the first element separation pattern 105 in a vertical direction perpendicular to the upper surface of the first substrate 110.

In an exemplary embodiment, a slope of the side surface of the support structure SS in the first element separation pattern 105 may be different from a slope of the side surface of the support structure SS in remaining portions of the first substrate 110. For example, as shown in the exemplary embodiments of FIGS. 4 and 5, the slope of the side surface of the support structure SS in the portions of the first substrate 110 outside of the first element separation pattern 105 may be greater than the slope of the side surface of the support structure SS in the first element separation pattern 105. The differences in the slope may be due to, but is not limited to, the characteristics of the etching process for forming a support trench SSt.

In an exemplary embodiment, the support structure SS may include an insulating material. For example, the support structure SS may include at least one compound selected from silicon oxide, silicon nitride, silicon oxynitride, aluminum oxide and tantalum oxide. In an exemplary embodiment, the support structure SS may include silicon oxide.

Although a boundary between the support structure SS and the pixel separation pattern 120 is shown in FIGS. 3 to 5, this is only for convenience of explanation, and the technical idea of the present inventive concepts are not limited thereto. For example, in embodiments in which the support structure SS and the spacer film 122 are formed of the similar material, the boundary between the support structure SS and the spacer film 122 may not exist.

In an exemplary embodiment, a potential barrier layer 113 extending along the side surfaces of the pixel separation pattern 120 and the side surfaces of the support structure SS may be disposed in the first substrate 110. For example, as shown in the exemplary embodiment of FIG. 5, a partial portion of the potential barrier layer 113 may be disposed in the first substrate 110 extending along the side surface of the pixel separation pattern 120, and another portion of the potential barrier layer 113 may be disposed in the first substrate 110 extending along the side surfaces of the support structure SS. The potential barrier layer 113 may conformally extend along the side surfaces of the pixel separation pattern 120 and the side surfaces of the support structure SS.

The potential barrier layer 113 may have a conductivity type that is opposite to the conductivity type of the photoelectric conversion layer PD. For example, when the photoelectric conversion layer PD contains n-type impurities, the potential barrier layer 113 may be formed by ion-implantation of the p-type impurities. Accordingly, the potential barrier layer 113 may reduce a dark current to improve the quality of the image sensor according to an exemplary embodiment of the present inventive concepts. For example, the potential barrier layer 113 may reduce generation of dark current due to electron-hole pairs (EHP) generated from surface defects of the pixel separation trench 120t.

The first wiring structure IS1 may be disposed on the first substrate 110. In an exemplary embodiment, the first wiring structure IS1 may be disposed on the second surface 110b of the first substrate 110.

The first wiring structure IS1 may be made up of one or a plurality of wirings. For example, the first wiring structure IS1 may include a first inter-wiring insulation film 130, and a first wiring 132 in the first inter-wiring insulation film 110 The number of layers of wirings of the first wiring structure IS1 and the arrangement thereof shown in the exemplary embodiment of FIG. 4 are merely examples In other exemplary embodiments of the present inventive concepts, the number of the layers of wirings of the first wiring structure IS1 and the arrangement thereof may vary.

In an exemplary embodiment of the present inventive concepts, the first wiring 132 may be electrically connected to the plurality of unit pixels, such as the first to ninth unit pixels PX1 to PX9. For example, the first wiring 132 may be electrically connected to the first electronic element TR1.

The surface insulation film 140 may be disposed on the first: substrate 110. In an exemplary embodiment, the surface insulation film 140 may extend along the first surface 110a of the first substrate 110. In some exemplary embodiments, the surface insulation film 140 may be in direct contact with the pixel separation pattern 120 and the support structure SS.

In an exemplary embodiment, the surface insulation film 140 may include an insulating material. For example, in an exemplary embodiment, the surface insulation film 140 may include at least one compound selected from silicon oxide, silicon nitride, silicon oxynitride, aluminum oxide and hafnium oxide. However, exemplary embodiments of the present inventive concepts are not: limited thereto.

In so e exemplary embodiments, the surface insulation film 140 may be formed of multi-films. For example, in an exemplary embodiment, the surface insulation film 140 may include an aluminum oxide film, a hafnium oxide film, a silicon oxide film, a silicon nitride film and a hafnium oxide film, which are sequentially stacked on the first surface 110a of the first substrate 110. However, exemplary embodiments of the present inventive concepts are not limited thereto.

The surface insulation film 140 may function as a reflection prevention film to prevent reflection of light incident on the first substrate 110, thereby increasing the photo receiving rate of the photoelectric conversion layer PD. Further, the surface insulation film 140 may function as a flattening film for forming a color filter 170 and a microlens 180 to be described later with a uniform height.

The color e 170 may be disposed on the surface insulation film 140. The color filter 170 may be arranged to correspond to each of the plurality of unit pixels, such as the first to ninth unit pixels PX1 to PX9. For example, the plurality of color filters 170 may be arranged two-dimensionally (e.g., in the form of a matrix) on a plane defined in the first direction X and the second direction Y.

The color filter 170 may have various color filters in accordance with the plurality of unit pixels, such as the first to ninth unit pixels PX1 to PX9. For example, the color filters 170 may be arranged in a bayer pattern including a red color filter, a green color filter and a blue. color filter. However, exemplary embodiments of the present inventive concepts are not limited thereto. For example, in another exemplary embodiment, the color filter 170 may include a yellow filter, a magenta filter, and a cyan filter, and may further include a white filter.

In some exemplary embodiments, grid patterns including a conductive pattern 150 and a low-refractive index pattern 160 may be formed between the color filters 170 (e.g., in a direction parallel to the first surface 110a of the first substrate 110). The grid patterns may be disposed on the surface insulation film 140. For example, as shown in the exemplary embodiment of FIG. 4, a lower surface of the grid patterns including the conductive pattern 150 and the low-refractive index pattern 160 may be disposed directly on an upper surface of the surface insulation film 140. The grid patterns may be formed in a grid shape in a plan view (e.g., in a plat e defined in the first direction X and the second direction Y) and may be interposed between the color filters 170. In some exemplary embodiments, the grid patterns including the conductive pattern 150 and the low-refractive index pattern 160 may be placed to overlap the pixel separation pattern 120 in the vertical direction perpendicular to the upper surface of the first substrate 110.

In some exemplary embodiments, the grid patterns may include the conductive pattern 150 and the low-refractive index pattern 160. The conductive pattern 150 and the low-refractive index pattern 160 may be, for example, sequentially stacked on the surface insulation film 140. For example, as shown in the exemplary embodiment of FIG. 4, a lower surface of the low-refractive index pattern 160 may directly contact an upper surface of the conductive pattern 150.

In an exemplary embodiment, the conductive pattern 150 may include a conductive material. For example, the conductive pattern 150 may include at least one compound selected from titanium (Ti), titanium nitride (TiN), tantalum (Ta), tantalum nitride (TaN), tungsten (W), aluminum (Al) and copper (Cu). However, exemplary embodiments of the present inventive concepts are not limited thereto. The conductive pattern 150 may prevent charges generated by ESD or the like from being accumulated on the surface of the first substrate 110 (e.g., the first surface 110a) to effectively prevent the ESD bruise defect.

The low-refractive index pattern 160 may include a low-refractive index material having a refractive index that is lower than silicon (Si). For example, in an exemplary embodiment, the low-refractive index pattern 160 may include at least one compound selected from silicon oxide, aluminum oxide and tantalum oxide. However, exemplary embodiments of the present inventive concepts are not limited thereto. The low-refractive index pattern 160 may increase the light collection efficiency by refracting or reflecting the light that is obliquely incident, thereby increasing the quality of the image sensor.

In some exemplary embodiments, a first protective film 165 may be disposed on the surface insulation film 140 and the grid patterns. For example, the first protective film 165 may conformally extend along the profiles of the upper surface of the surface insulation film 140, and the side surfaces and the upper surfaces of the grid patterns.

In an exemplary embodiment, the first protective film 165 may include aluminum oxide. However, exemplary embodiments of the present inventive concepts are not limited thereto. The first protective film 165 ma prevent the surface insulation film 140 and the grid patterns from being damaged.

The microlens 180 may be disposed on the color filter 170. The microlens 180 may be arranged to correspond to each of the plurality of unit pixels, such as the first to ninth unit pixels PX1 to PX9. For example, the plurality of microlenses 180 may be arranged two-dimensionally (e.g., in the form of a matrix) on the plane including the first direction X and the second direction Y.

As shown in the exemplary embodiment of FIGS. 4-5, the microlens 180 has a convex shape and may have a predetermined radius of curvature. Therefore, the microlens 180 may concentrate the light incident on the photoelectric conversion layer PD. In an exemplary embodiment, the microlens 180 may include a light transmissive resin. However, exemplary embodiments of the present inventive concepts are not limited thereto.

In some exemplary embodiments, a second protective film 185 may be disposed on the microlens 180. The second protective film 185 may extend along the surface of the microlens 180. In an exemplary embodiment, the second protective film 185 may include, for example, an inorganic oxide film. For example, the second protective film 185 may include, but is not limited to, at least one compound selected from silicon oxide, titanium oxide, zirconium oxide and hafnium oxide. In some exemplary embodiments, the second protective film 185 may include low temperature oxide (LTO).

The second protective film 185 may protect the microlens 180 from the outside. For example, the second protective film 185 may include an inorganic oxide film to protect the microlens 180 including an organic substance. Further, the second protective film 185 may increase the quality of the image sensor by increasing the light collection efficiency of the microlens 180. For example, the second protective film 185 may reduce reflection, refraction, scattering or the like of incident light that reaches a space between the microlenses 180, by filling the space between the microlenses 180.

As the image sensor becomes highly integrated, the size of the unit pixel gradually decreases, and an aspect ratio (AR) of the pixel separation pattern that separates the unit pixels gradually increases to compensate for the decrease in size. However, the increased aspect ratio of the pixel separation pattern causes a leaning phenomenon of the unit pixel, which causes a defect of the image sensor.

For example, referring to a comparative embodiment shown in FIG. 6, as the aspect ratio of the pixel separation pattern 120 increases, a pattern shift due to a leaning phenomenon may occur in the first pixel PX1 and the second pixel PX2.

However, the image sensor according to an exemplary embodiments of the present inventive concepts may include a support structure SS to support the unit pixels. For example, as described above, the support structure SS may be positioned to correspond to the grid points of the pixel separation pattern 120 and support the adjacent unit pixels of the plurality of unit pixels, such as the first to ninth unit pixels PX1 to PX9, thereby preventing the leaning phenomenon of the unit pixels. As a result, an image sensor with increased product reliability and quality may be provided.

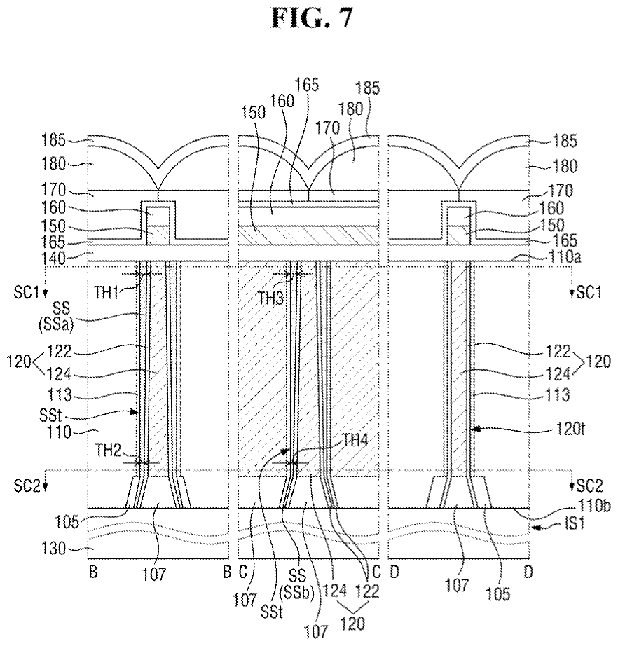

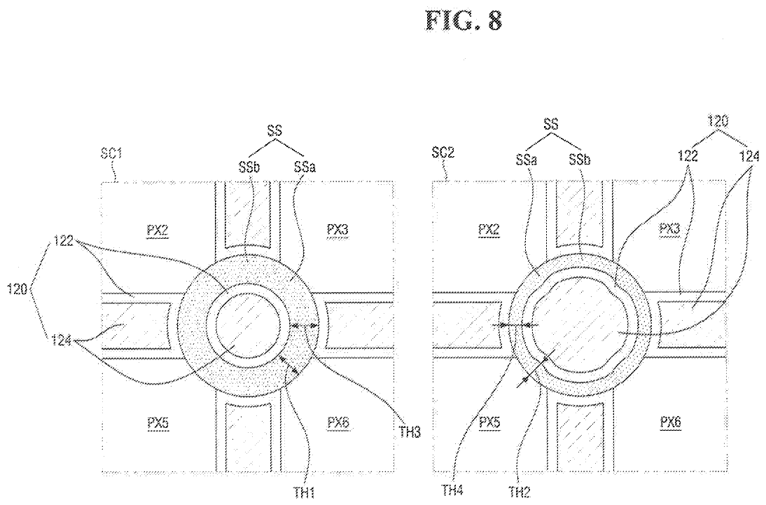

FIG. 7 is a cross-sectional view for explaining an image sensor according to an exemplary embodiment of the present inventive concepts. FIG. 8 is a cross sectional view taken along lines SC1-SC1 and SC2-SC2 of FIG. 7. For convenience of explanation, substantially identical elements that were explained above with respect to the exemplary embodiments of FIGS. 1 to 6 will be briefly described or omitted.

Referring to FIGS. 7 and 8, in the image sensor according to some exemplary embodiments, a thickness of the support structure SS decreases from the first surface 110a of the first substrate 110 toward the second surface 110b of the first substrate 110.

For example, thicknesses TH2 and TH4 of the support structure SS adjacent to the second surface 110b of the first substrate 110 may be less than the thicknesses TH1 and TH3 of the support structures SS adjacent to the first surface 110a of the first substrate 110.

As previously described, the spacer film 122 may conformally extend along a portion of the side surface of the support structure SS. Therefore, the sum of thicknesses of the support structure SS and the spacer film 122 may decrease from the first surface 110a of the first substrate 110 towards the second surface 110 of the first substrate 110.

From a plan view, the thickness of the support structure SS may or may not be uniform along the periphery of the support trench SSt. For example, as shown in FIG. 8, the support structure SS may include a first portion SSa which does not overlap the pixel separation trench 120t formed in a grid shape, and a second portion SSb which overlaps the pixel separation trench 120t formed in a grid shape. In an exemplary embodiment, the thickness of the first portion SSa of the support structure SS may be the same as or different from the thickness of the second portion SSb of the support structure SS.

In an exemplary embodiment, the first portion SSa of the support structure SS may have an outer surface that is in direct contact with the plurality of unit pixels, such as the first to ninth unit pixels PX1 to PX9, and the second portion SSb of the support structure SS may have may have an outer surface that is in direct contact with the pixel separation pattern 120.

A region SC1 of FIG. 8 is a diagram for explaining the cross-section of the support structure SS adjacent to the first surface 10a of the first substrate 110. Referring to the region SC1 of FIG. 8, in some exemplary embodiments, a thickness TH1 of the first portion SSa of the support structure SS may be the same as a thickness TH3 of the second portion SSb of the support structure SS. In the present specification, the term “same” means an identical value as well as a value that has a minute difference that may occur due to a process margin or the like.

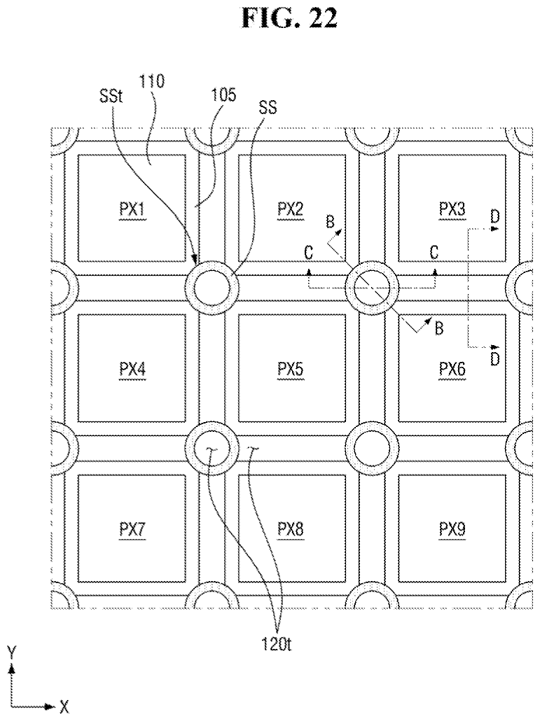

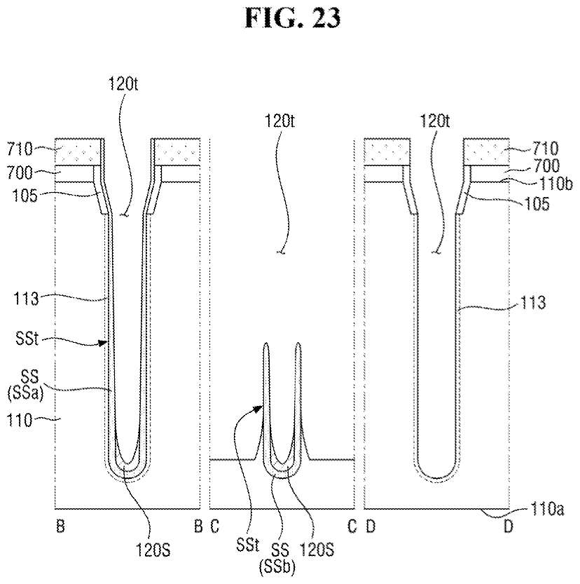

A region SC2 of FIG. 8 is a diagram for explaining a cross-section of the support structure SS adjacent to the second surface 110b of the first substrate 110. Referring to region SC2 of FIG. 8, in some exemplary embodiments, a thickness TH2 of the first portion SSa of the support structure SS may be greater than a thickness TH4 of the second portion SSb of the support structure SS. This may be due to the characteristics of the etching process for forming the pixel separation trench 120t. This will be described more specifically below in the explanation of the exemplary embodiments of FIGS. 22 and 23.

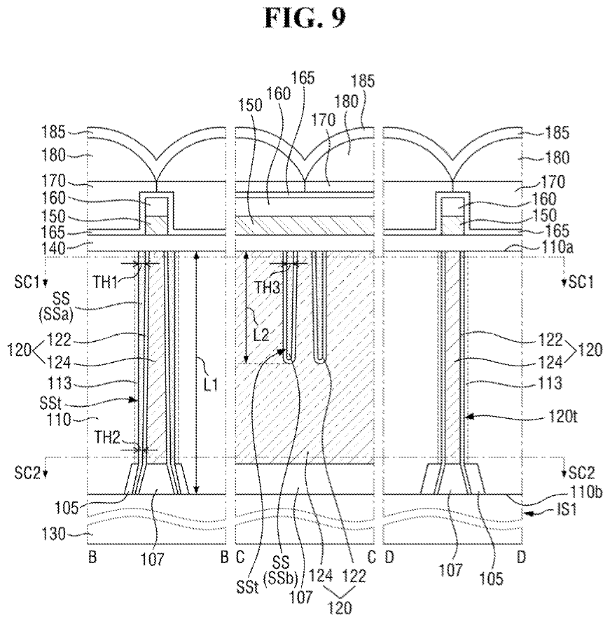

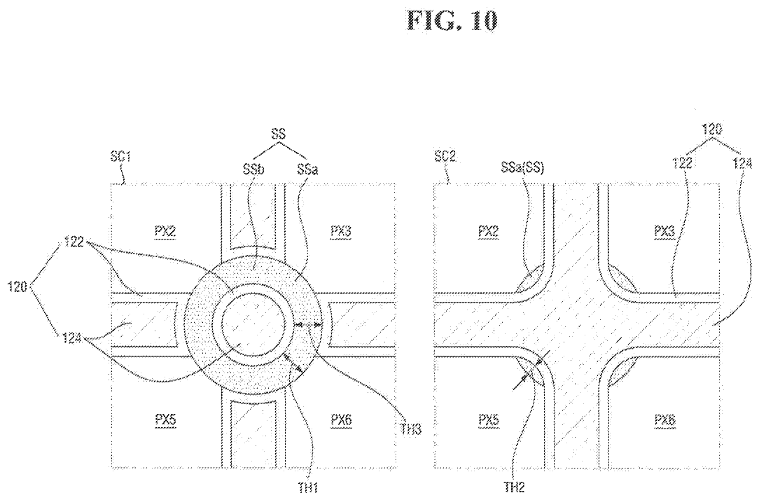

FIG. 9 is a cross-sectional view for explaining an image sensor according to some exemplary embodiments of the present inventive concepts. FIG. 10 is a cross-sectional view taken along lines SC1-SC1 and SC2-SC2 of FIG. 9. For convenience of explanation, substantially identical elements that were explained above with respect to the exemplary embodiments of FIGS. 1 to 8 will be briefly described or omitted.

Referring to FIGS. 9 and 10, in the image sensor according to some exemplary embodiments, the height of the first portion SSa of the support structure SS is greater than the height of the second portion SSb of the support structure SS.

For example, a length L2 in which the second portion SSb of the support structure SS extends in the vertical direction perpendicular to an upper surface of the first substrate 110 may be less than a length L1 in which the first portion SSa of the support structure SS extends vertically. For example, as shown in the exemplary embodiment of FIG. 9, a lower surface of the second portion SSb of the support structure SS may be spaced apart from the second surface 110b of the first substrate 110.

The pixel separation pattern 120 may cut a portion of the support structure SS. For example, referring to region SC2 of FIG. 8, the pixel separation pattern 120 may cut the support structure SS adjacent to the second surface 110b. Accordingly, the support structure SS may not connect the unit pixels (e.g., the second, third, fifth and sixth pixels PX2, PX3, PX5 and PX6) adjacent to the second surface 110b to each other.

The pixel separation pattern 120 may not cut the other portion of the support structure SS. For example, referring to the region SC1 of FIG. 8, the pixel separation pattern 120 may not cut the support structure SS adjacent to the first surface 110a. Accordingly, the support structure SS may connect the unit pixels (e.g., the second, third, fifth and sixth pixels PX2, PX3, PX5 and PX6) adjacent to the first surface 110a to each other.

In some exemplary embodiments, the thickness TH2 of the first portion SSa of the support structure SS adjacent to the second surface 110b may be smaller than the thickness TH1 of the support structure SS adjacent to the first surface 110a.

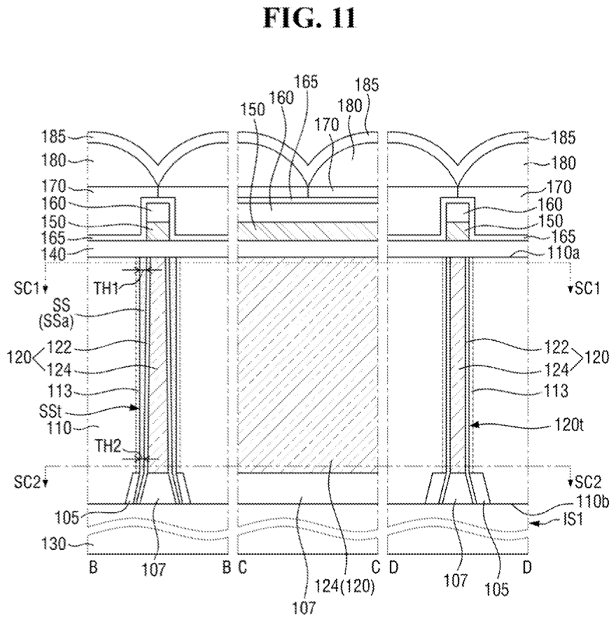

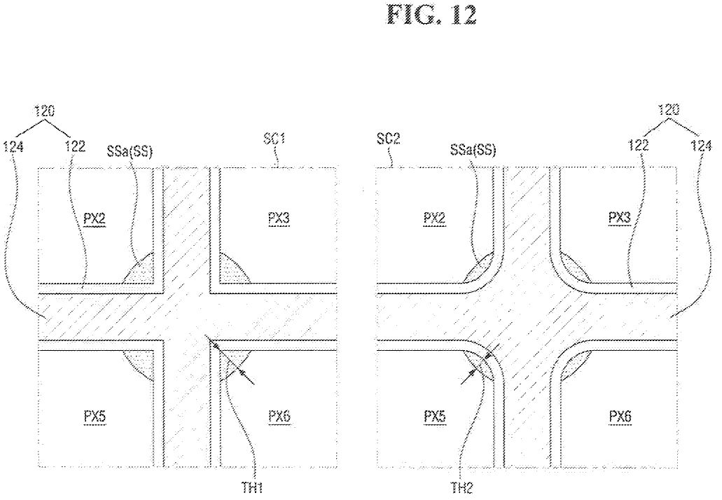

FIG. 11 is a cross-sectional view for explaining an image sensor according to some exemplary embodiments of the present inventive concepts. FIG. 12 is a cross-sectional view taken along lines SC1-SC1 and SC2-SC2 of FIG. 9. For the sake of convenience of explanation, substantially identical elements that were explained above with respect to the exemplary embodiments of FIGS. 1 to 10 will be briefly described or omitted.

Referring to FIGS. 11 and 12, in the image sensor according to some exemplary embodiments, the pixel separation pattern 120 may completely cut the support structure SS.

For example, referring to FIG. 8, the pixel separation pattern 120 may also cut the support structure SS adjacent to the first surface 110a as well as the support structure SS adjacent to the second surface 110b. As a result, the second portion SSb of the support structure SS described above in the exemplary embodiments of FIGS. 7 and 8 may be completely removed. Also, the support structure SS may not be formed inside the pixel separation pattern 120.

In some exemplary embodiments, the thickness TH2 of the first portion SSa of the support structure SS adjacent to the second surface 110b may be less than the thickness TH1 of the support structure SS adjacent to the first surface 110a.

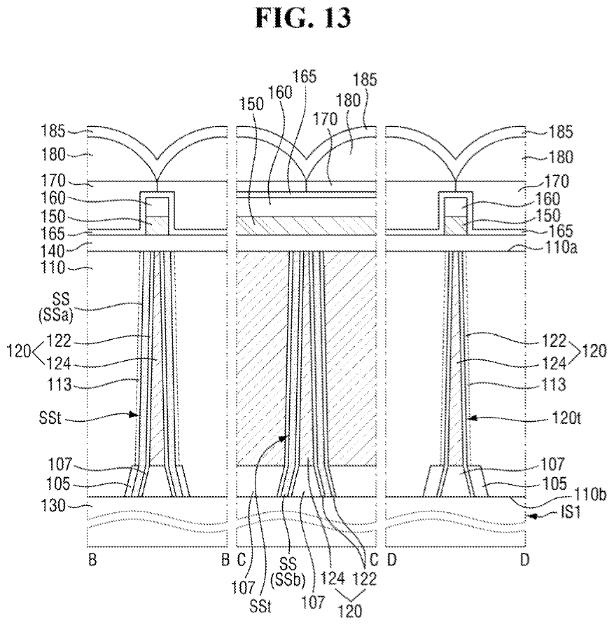

FIG. 13 is a cross-sectional view for explaining an image sensor according to some exemplary embodiments, For convenience of explanation, substantially identical elements that were described above with respect to the exemplary embodiments of FIGS. 1 to 12 will be briefly described or omitted.

Referring to FIG. 13, in the image sensor according to some exemplary embodiments, the width of the support structure SS decreases from the second surface 110b of the first substrate 110 towards the first surface 110a of the first substrate 110.

The decreasing width from the second surface 110b of the first substrate 110 towards the first surface 110a of the first substrate 110 may be due to the characteristics of the etching process for forming the support trench SSt. For example, the process of etching the first substrate 110 to form the support trench SSt may be performed on the second surface 110b of the first substrate 110.

In some exemplary embodiments, the width of the pixel separation pattern 120 may decrease from the second surface 110b of the first substrate 110 towards the first surface 110a of the first substrate 110.

The decreasing width of the pixel separation pattern 120 from the second surface 110b of the first substrate 110 towards the first surface. 110a If the first substrate 110 may be due to the characteristics of the etching process for forming the pixel separation trench 120t. For example, the process of etching the first substrate 110 to form the pixel separation trench 120t may be performed on the second surface 110b of the first substrate 110.

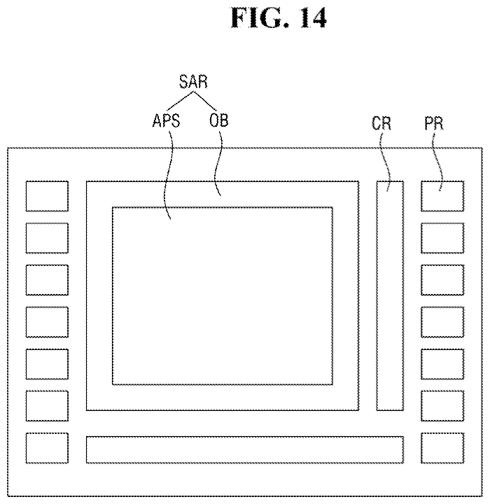

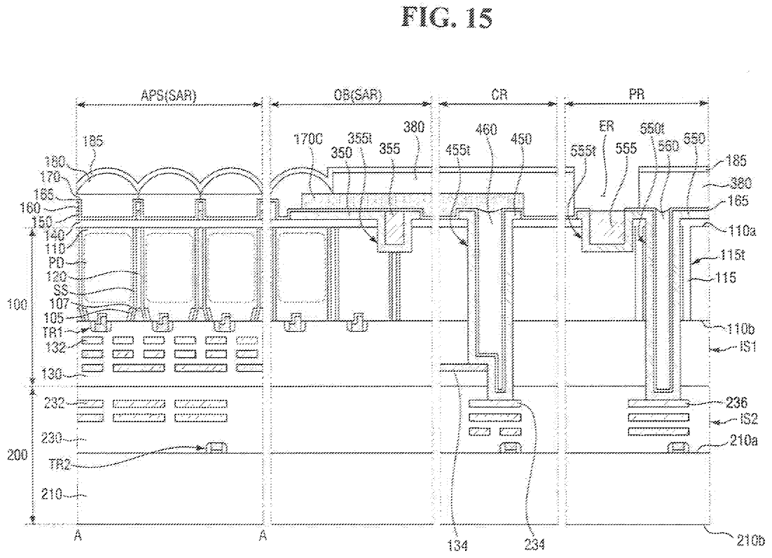

FIG. 14 is a layout diagram for explaining an image sensor according to some exemplary embodiments. FIG. 15 is a cross-sectional view for explaining the image sensor of FIG. 14. For the sake of convenience of explanation, substantially identical elements that were described above with respect to the exemplary embodiments of FIGS. 1 to 13 will be briefly described or omitted.

Referring to FIGS. 14 and 15, an image sensor according to some exemplary embodiments includes a sensor array region SAR, a connection region CR and a pad region PR.

The sensor array region SAR may include a region corresponding to the active pixel sensor array 10 of the exemplary embodiment of FIG. 1. For example, a plurality of unit pixels arranged two-dimensionally (e.g., in the form of a matrix) may be formed in the sensor way region SAR.

The sensor array region SAR may include a photo receiving region APS and a photo blocking region OB. Active pixels provided with light to generate an active signal may be arranged in the photo receiving region APS. Optical black pixels that block light to generate an optical black signal may be arranged in the photo blocking region OB. Although in the exemplary embodiment of FIG. 14, the photo blocking region OB is shown as being disposed along the periphery of the photo receiving region APS and surrounding the photo receiving region APS, exemplary embodiments of the present inventive concepts are not limited thereto. 1001291 In some exemplary embodiments, the photoelectric conversion layer PD may not be disposed in a portion of the photo blocking region OB. For example, the photoelectric conversion layer PD may be disposed in the portion of the first substrate 110 of the photo blocking region OB that is adjacent to the photo receiving region APS, but may not be disposed in the first substrate 110 of the portion of the photo blocking region OB that is spaced apart from the photo receiving region APS.

In some exemplary embodiments, dummy pixels may be disposed in the phots receiving region APS adjacent to the photo blocking region OB.

The connection region CR may be disposed around the sensor array region SAR. While the exemplary embodiment of FIG. 14 shows the connection region CR disposed on one side of the sensor array region SAR, exemplary embodiments of the present inventive concepts are not limited thereto and the connection region CR may be variously arranged with respect to the sensor array region SAR. Wirings are disposed in the connection region CR and may be configured to transmit and receive electric signals from the sensor array region SAR.

The pad region PR may be disposed around the sensor array region SAR. Although the exemplary embodiment of FIG. 14 shows the pad region PR disposed to be adjacent to an edge of the image sensor, exemplary embodiments of the present inventive concepts are not limited thereto and the pad region PR may be variously arranged with respect to the image sensor. The pad region PR may be configured to be connected to an external device or the like to transmit and receive air electric signal between the image sensor according to some exemplary embodiments and an external device.

In the exemplary embodiment of FIG. 14, although the connection region CR is shown as being positioned between the sensor array region SAR and the pad region PR, exemplary embodiments of the present inventive concepts are not limited thereto. For example, the positioning of the sensor array region SAR, the connection region CR and the pad region PR may be variously arranged in other exemplary embodiments.

In the image sensor according to some exemplary embodiments, the first substrate 110 and the first wiring structure IS1 may form a first substrate structure 100

As shown in the exemplary embodiment of FIG. 15, the first wiring structure IS1 may include a first, wiring 132 in the sensor array region SAR and a second wiring 134 in the connection region CR. The first wiring 132 may be electrically connected to the plurality of unit pixels, such as the first to ninth unit pixels PX1 to PX9 of the sensor array region SAR. For example, the first wiring 132 may be connected to the first electronic element TRI. The second wiring 134 may extend from the sensor array region SAR. For example, the second wiring 134 may be electrically connected to at least a portion of the first wiring 132. As a result, the second wiring 134 may be electrically connected to the plurality of unit pixels, such as the first to ninth unit pixels PX1 to PX9 of the sensor array region SAR.

The image sensor according to some exemplary embodiments may include a second substrate 210 and a second wiring structure IS2.

In an exemplary embodiment, the second substrate 210 may be bulk silicon or SOI (silicon-on-insulator). For example, the second substrate 210 may be a silicon substrate or may include other materials, such as at least one compound selected from silicon germanium, indium antimonide, lead telluride, indium arsenide, indium phosphide, gallium arsenide and gallium antimonide. Alternatively, the second substrate 210 may have an epitaxial layer disposed on the base substrate.

The second substrate 210 may include a third surface 210a and a fourth surface 210b that are opposite to each other. As shown in the exemplary embodiment of FIG. 15, the third surface 210a of the second substrate 210 may be a surface that faces the second surface 110b of the first substrate 110.

A plurality of electronic elements may be disposed on the second substrate 210. For example, the second electronic element TR2 may be disposed on the third surface 210a of the second substrate 210. The second electronic element TR2 may be electrically connected to the sensor array region SAR, to transmit and receive an electric signal to and from each unit pixel of the sensor array region SAR. For example, the second electronic element TR2 may include electronic elements that form the row decoder 20, the row driver 30, the column decoder 40, the timing generator 50, the correlated double sampler 60, the analog-to-digital convener 70 or the input/output buffer 80 of the exemplary embodiment of FIG. 1.

The second wiring structure IS2 may be disposed on the second substrate 210. As shown in the exemplary embodiment of FIG. 15, the second wiring structure IS2 may be disposed on the third surface 210a of the second substrate 210. The second substrate 210 and the second wiring structure IS2 may form a second substrate structure 200.

The second wiring structure IS2 may be attached to the first wiring structure IS1. For example, as shown in the exemplary embodiment of FIG. 15, the upper surface of the second wiring structure IS2 may directly contact, and be attached to, the lower surface of the first wiring structure IS1.

In an exemplary embodiment, the second wiring structure IS2 may include one or more wirings. For example, the second wiring structure IS2 may include a second inter-wiring insulation film 230, and a plurality of wirings including third to fifth wirings 232, 234 and 236 in the second inter-wiring insulation film 230. In FIG. 15, the number of layers of wirings forming the second wiring structure IS2, the arrangement thereof and the like are merely examples, and exemplary embodiments of the present inventive concepts are not limited thereto.

At least some of the plurality of wirings, such as the third to fifth wirings 232, 234 and 236 of the second wiring structure IS2 may be connected to the second electronic element TR2. As shown in the exemplary embodiment of FIG. 15, the second wiring structure IS2 may include the third wiring 232 in the sensor array region SAR, the fourth wiring 234 in the connection region CR, and the fifth wiring 236 in the pad region PR. As shown in the exemplary embodiment of FIG. 15, the fourth wiring 234 may be an uppermost wiring among the plurality of wirings in the connection region CR, and the fifth wiring 236 may be an uppermost wiring among the plurality of wirings in the pad region PR.

The image sensor according to some exemplary embodiments may include a first connection structure 350, a second connection structure 450, and a third connection structure 550.

As shown in the exemplary embodiment of FIG. 15, the first connection structure 350 may be disposed in the photo blocking region OB. The first connection structure 350 may be disposed on the surface insulation film 140 of the photo blocking region OB. The first connection structure 350 may be in direct contact with the pixel separation pattern 120. For example, a first trench 355t which exposes the pixel separation pattern 1 may be formed in the first substrate 110 and the surface insulation film 140 of the photo blocking region OB. The first connection structure 350 may be disposed in the first trench 355t and be in direct contact with the pixel separation pattern 120 in the photo blocking region OB. As shown in the exemplary embodiment of FIG. 15, the first connection structure 350 may extend along the profiles of the side surfaces and the lower surface of the first trench 355t. However, exemplary embodiments of the present inventive concepts ate not limited thereto.

In an exemplary embodiment, the first connection structure 350 may include at least one compound selected from titanium (Ti), titanium nitride (TiN), tantalum (Ta), tantalum nitride (TaN), tungsten (W), aluminum (Al) and copper (Cu).

In some exemplary embodiments, the first connection structure 350 is electrically connected to the pixel separation pattern 120 and may apply a ground voltage or a negative voltage to the pixel separation pattern 120. Therefore, the charges generated by the ESD or the like may be discharged to the first connection structure 350 through the pixel separation pattern 120, and an ESD bruise defect may be effectively prevented.

In some exemplary embodiments, a first pad 355 which fills the first trench 355t may be formed on the first connection structure 350. In an exemplary embodiment, the first pad 355 may include, for example, but is not limited to, at least one of tungsten (W), copper (Cu), aluminum (Al), gold (Au), silver (Ag), and alloys thereof.

In some exemplary embodiments, the first protective film 165 may cover the first connection structure 350 and the first pad 355. For example, the first protective film 165 may extend along the profiles of the first connection structure 350 and the first pad 355.

The second connection structure 450 may be disposed in the connection region CR. As shown in the exemplary embodiment of FIG. 15, the second connection structure 450 may be disposed on the surface insulation film 140 of the connection region CR. The second connection structure 450 may electrically connect the first substrate structure 100 and the second substrate structure 200. For example, a second trench 455t that exposes the second wiring 134 and the fourth wiring. 234 may be formed in the first substrate structure 100 and the second substrate structure 200 of the connection region CR. The second connection structure 450 may be disposed in the second trench 455t to connect the second wiring 134 and the fourth wiring 234. As shown n the exemplary embodiment of FIG. 15, the second connection structure 450 may extend along the profiles of the side surfaces and the lower surface of the second trench 455t. However, exemplary embodiments of the present inventive concepts are not limited thereto.

In an exemplary embodiment, the second connection structure 450 may include at least one compound selected from titanium (Ti), titanium nitride (TiN), tantalum (Ta), tantalum nitride (TaN), tungsten (W), aluminum (Al), copper (Cu) and combinations thereof. However, exemplary embodiments of the present inventive concepts are not limited thereto. In some exemplary embodiments, the second connection structure 450 may be disposed at the same level as the first connection structure 350. As used herein, the expression “formed at the same level” means that both are formed by the same fabricating process and may be disposed at a substantially same distance (e.g., in the vertical direction) from the fourth surface 210b of the second substrate 210.

In some exemplary embodiments, the first protective film 165 may cover the second connection structure 450. For example, the first protective film 165 may extend along the profile of the second connection structure 450.

In some exemplary embodiments, a first filling insulation film 460 thatIin an exemplary embodiment, the first filling insulation film 460 may include at least one compound selected from silicon oxide, aluminum oxide and tantalum oxide. However, exemplary embodiments of the present inventive concepts are not limited thereto.

The third connection structure 550 may be disposed in the pad region PR. As shown in the exemplary embodiment of FIG. 15, the third connection structure 550 may be disposed on the surface insulation film 140 of the pad region PR. The third connection structure 550 may electrically connect the second substrate structure 200 to an external device or the like.

For example, a third trench 550t that exposes the fifth wiring 236 may be formed in the first substrate structure 100 and the second substrate structure 200 of the pad region PR. As shown in the exemplary embodiment of FIG. 15, the third connection structure 550 is disposed in the third trench 550t and may be in direct contact with the fifth wiring 236. In addition, a fourth trench 555t may be formed in the first substrate 110 of the pad region PR adjacent to the third trench 550t. The third connection structure 550 may be formed in the fourth trench 555t and may be exposed. As shown in the exemplary embodiment of FIG. 15, the third connection structure 550 may extend along profiles of the side surfaces and the lower surfaces of the third trench 550t and the fourth trench 555t. However, exemplary embodiments of the present inventive concepts are not limited thereto.

The third connection structure 550 may include, for example, but is not limited to, at least one of titanium (Ti), titanium nitride (TiN), tantalum (Ta), tantalum nitride (TaN), tungsten (W), aluminum (Al), copper (Cu) and combinations thereof. In some exemplary embodiments, the third connection structure 550 may be disposed at the same level as the first connection structure 350 and the second connection structure 450.

In some exemplary embodiments, a second filling insulation film 560 that fills the third trench 550t may be disposed on the third connection structure 550. The second filling insulation film 560 may include, for example, but is not limited to, at least one compound selected from silicon oxide, aluminum oxide and tantalum oxide. However, exemplary embodiments of the present inventive concepts are not limited thereto. In some exemplary embodiments, the second filling insulation film 560 may be disposed at the same level as the first filling insulation film 460.

As shown in the exemplary embodiment of FIG. 15, a second pad 555 that fills the fourth trench 555t may be disposed on the third connection structure 550. In an exemplary embodiment, the second pad 555 may include, for example, but is not limited to, at least one compound selected from tungsten (W), copper (Cu), aluminum (Al), gold (Au), silver (Ag), and alloys thereof. In some exemplary embodiments, the second pad 555 may be formed at the same level as the first pad 355.

As shown in the exemplary embodiment of FIG. 15, the first protective film 165 may cover the third connection structure 550. For example, the first protective film 165 may extend along the profile of the third connection structure 550. In some exemplary embodiments, the first protective film 165 may expose the second pad 555.

In some exemplary embodiments, a second element separation pattern 115 may be disposed in the first substrate 110. For example, an element separation trench 115t may be formed in the first substrate 110. The second element separation pattern 115 may be disposed in the element separation trench 115t.

While the second element separation pattern 115 shown in the exemplary embodiment of FIG. 15 is disposed only on the periphery of the third connection structure 550 of the pad region PR, exemplary embodiments of the present inventive concepts are not limited thereto. For example, in other exemplary embodiments, the second element separation pattern 115 may be variously arranged, such as to be disposed around the first connection structure 350 of the photo blocking region OB or around the second connection structure 450 of the connection region CR.

In an exemplary embodiment, the second element separation pattern 115 may include, for example, but is not limited to, at least one of silicon oxide, silicon nitride, silicon oxynitride, aluminum oxide, hafnium oxide, and combinations thereof. In some exemplary embodiments, the second element separation pattern 115 may be disposed at the same level as the surface insulation film 140.

In some exemplary embodiments, a photo blocking color filter 170C may be disposed on the first connection structure 350 and the second connection structure 450. For example, the photo blocking color filter 170C may be disposed to cover at least a partial portion of the first protective film 165 in the photo blocking region OB and the connection region CR. In an exemplary embodiment, the photo blocking color filter 170C may include, for example, but is not limited to, a blue color filter.

In come exemplary embodiments a third protective film 380 may be disposed on the photo blocking color filter 170C. For example, the third protective film 380 may be disposed to cover at least a partial portion of the first protective film 165 in the photo blocking region OB, the connection region CR and the pad region PR. In some exemplary embodiments, the second protective film 185 may extend along the surface of the third protective film 380. The third protective film 380 may include, for example, but is not limited to, a light transmissive resin. In some exemplary embodiments, the third protective film 380 may include the same material as the microlens 180.

In some exemplary embodiments, the second protective film 185 and the third protective film 380 may expose the second pad 555. For example, an exposure opening ER that exposes the second pad 555 may be formed in the second protective film 185 and the third protective film 380. Accordingly, the second pad 555 may be configured to be connected to an external device or the like to transmit and receive an electric signal between the image sensor according to sonic exemplary embodiments and the external device.

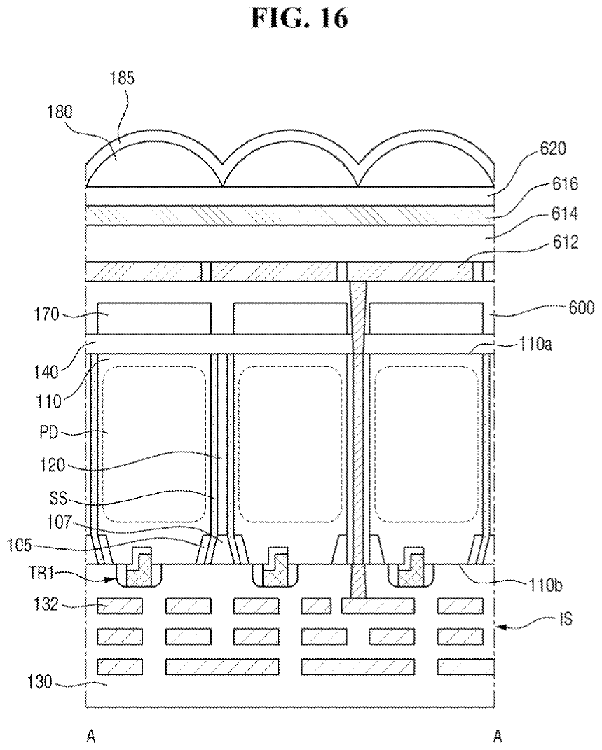

FIG. 16 is a cross-sectional view for explaining an image sensor according to some exemplary embodiments of the present inventive concepts. For the sake of convenience of explanation, substantially identical elements that were explained above with respect to the exemplary embodiments of FIGS. 1 to 15 will be briefly described or omitted.

Referring to FIG. 16, an image sensor according to some exemplary embodiments includes a lower electrode 612, an external photoelectric conversion layer 614 and an upper electrode 616.

The external photoelectric conversion layer 614 may be disposed outside the first substrate 110. For example, an interlayer insulation film 600 which covers the color filter 170 may be formed on the surface insulation film 140. The external photoelectric conversion layer 614 may be disposed on the interlayer insulation film 600. The external photoelectric conversion layer 614 may generate charges in proportion to the amount of light, incident from the outside. In some exemplary embodiments, the external photoelectric Conversion layer 614 may include an organic photodiode.

In some exemplary embodiments, the external photoelectric conversion layer 614 may detect green light. For example among the lights incident from the outside, light having a green wavelength may be absorbed by the external photoelectric conversion layer 614, Therefore, the external photoelectric conversion layer 614 may provide an electric signal concerning the detected green light. Light of other wavelengths except green light may pass through the external photoelectric conversion layer 614.

Also, in some exemplary embodiments, the photoelectric conversion layer PD may detect red or blue light. For example, light having passed through the external photoelectric conversion layer 614 may pass through the color filter 170 to provide red light or blue light to the photoelectric conversion layer PD. Accordingly, the photoelectric conversion layer PD may provide an electric signal concerning the detected red light or blue light.

As shown in the exemplary embodiment of FIG. 16, the lower electrode 612 may be disposed under the external photoelectric conversion layer 614. For example, the lower electrode 612 may be interposed between the interlayer insulation film 600 and the external photoelectric conversion layer 614 (e.g., in the vertical direction). The lower electrode 612 may be arranged to correspond to each of the plurality of unit pixels, such as the first to ninth unit pixels PX1 to PX9. For example, the plurality of lower electrodes 612 may be arranged two-dimensionally (e.g., in the form of a matrix) a plane defined in the first direction X and the second direction Y.

The upper electrode 616 may be disposed on the external photoelectric conversion layer 614. For example, the upper electrode 616 may extend along the upper surface of the external photoelectric conversion layer 614 and a lower surface of the upper electrode 616 may directly contact an upper surface of the external photoelectric conversion layer 614. Different levels of voltage may be applied to the lower electrode 612 and the upper electrode 616. Therefore, the electric signal generated fro M the external photoelectric conversion layer 614 may be directed to the lower electrode 612 or the upper electrode 616.

In an exemplary embodiment, the lower electrode 612 and the upper electrode 616 may include a transparent conductive material. For example, the lower electrode 612 and the upper electrode 616 may include, but are not limited to, at least one compound selected from ITO (indium Tin Oxide), ZnO (Zinc Oxide), SnO2 (Tin Dioxide) ATO (Antimony-doped Tin Oxide), AZO (Aluminum-doped Zinc Oxide), GZO (Gallium-doped Zinc Oxide), TiO₂ (Titanium Dioxide), FTO (Fluorine-doped Tin Oxide), and combinations thereof. In an exemplary embodiment, the upper electrode 616 may include the same material as the lower electrode 612, or may include a material different from the lower electrode 612.

In some exemplary embodiments, a fourth protective film 620 may be disposed between the upper electrode 616 and the microlens 180 (e.g., in the vertical direction). The fourth protective film 620 may protect the external photoelectric conversion layer 614. Further, the fourth protective film 620 may function as a flattening film for forming the color filter 170 and the microlens 180 at a uniform height.

In an exemplary embodiment, the fourth protective film 620 may include, but is not limited to, at least one compound selected from silicon oxide, silicon nitride, silicon oxynitride, aluminum oxide, hafnium oxide, and combinations thereof.

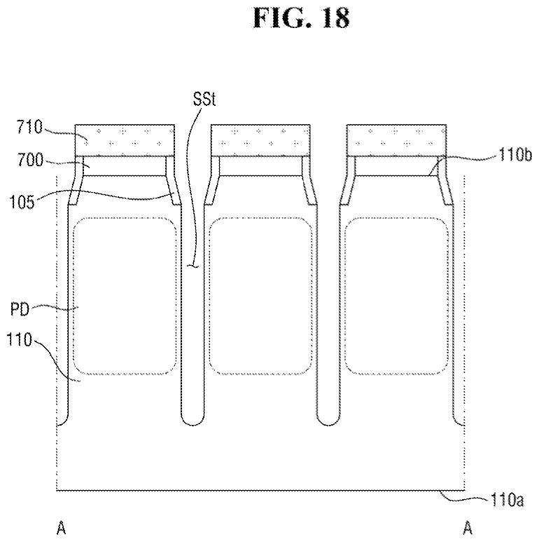

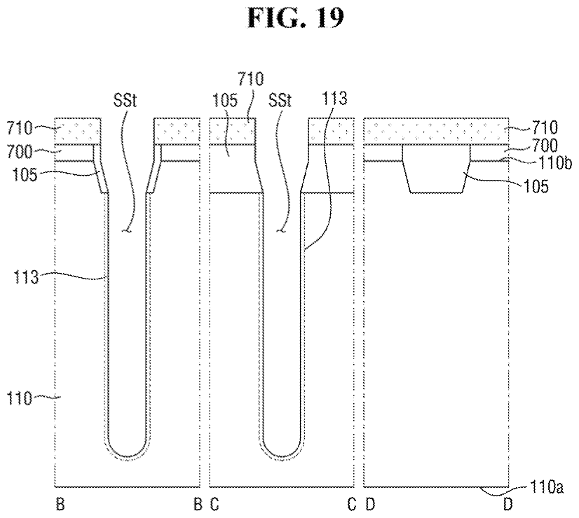

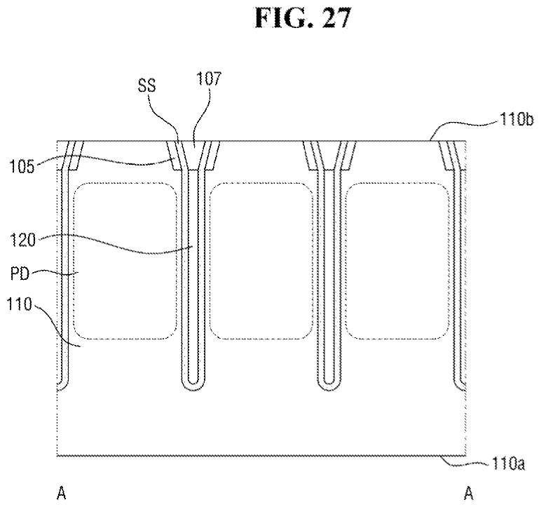

Hereinafter, a method for fabricating an image sensor according to some exemplary embodiments will be described with reference to the exemplary embodiments of FIGS. 1 to 30.

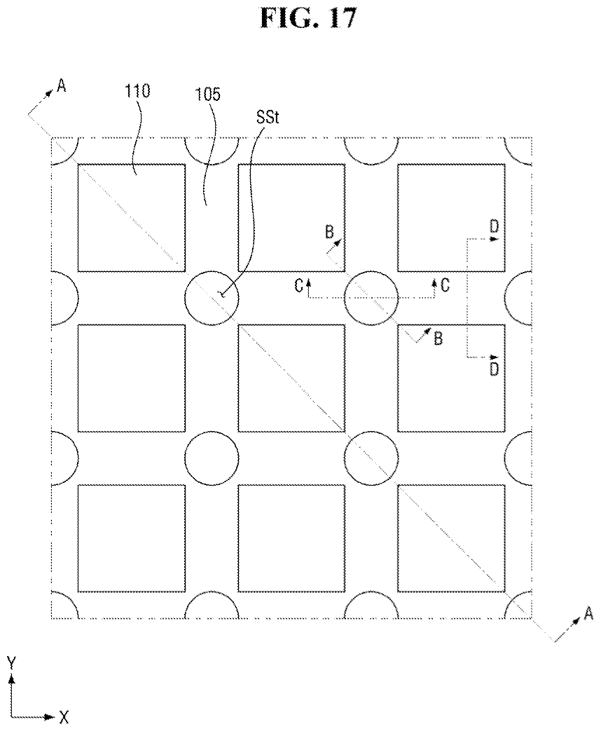

FIGS. 17 to 30 are intermediate stage diagrams for explaining a method for fabricating an image sensor according to some exemplary embodiments of the present inventive concepts.

For convenience of explanation, repeated parts of substantially identical elements that were described above with respect to the exemplary embodiments of FIGS. 1 to 16 will be briefly described or omitted.

Referring to the exemplary embodiments of FIGS. 17 to 19, a support trench SSt is formed in the first substrate 110.

In an exemplary embodiment, the first substrate 110 may be a semiconductor substrate. The first substrate 110 may include a first surface 110a and a second surface 110b that are opposite to each other (e.g., opposite in a vertical direction). A photoelectric conversion layer PD may be formed on the first substrate 110.

In some exemplary embodiments, the first element separation pattern 105 may be formed in the first substrate 110. For example, a flattening film 700 may be formed on the second surface 110b of the first substrate 110. In an exemplary embodiment, the flattening film 700 may include silicon nitride. However, exemplary embodiments of the present inventive concepts are not limited thereto. The first element separation pattern 105 may be formed, for example, by embedding an insulating material in a shallow trench formed by patterning the flattening film 700 and the first substrate 110.

The support trench SSt may be formed in the first substrate 110. The support trench SSt may be formed to correspond to a grid point of the pixel separation pattern 120 to be described below.

In some exemplary embodiments, the support trench SSt may be formed by performing an etching process on the second surface 110b of the first substrate 110. For example, a mask pattern 710 ma be formed on the flattening film 700. The mask pattern 710 may include openings corresponding to grid points of the pixel separation pattern 120 to be described below The first substrate 110 nay be etched using the mask pattern 710 as an etching mask and the support trench SSt may be formed in the first substrate 110.

In some exemplary embodiments, the support trench SSt may penetrate the first element separation pattern 105. For example, the opening of the mask pattern 710 may expose the first element separation pattern 105. The support trench SSt may fully penetrate the first element separation pattern 105.

In some exemplary embodiments, after forming the support trench SSt, a potential barrier layer 113 may be formed in the first substrate 110 exposed by the support trench SSt. In an exemplary embodiment, the potential barrier layer 113 may be formed in the first substrate 110 and may extend along the side surface of the support trench SSt.

For example, a plasma doping (PLAD) ion implantation process may be performed after forming the support trench SSt. The potential barrier layer 113 may have a conductivity type that is opposite to the conductivity type of the photoelectric conversion layer PD. For example, in an exemplary embodiment in which the photoelectric conversion layer PD includes n-type impurities, the potential barrier layer 113 may be formed by ion-implantation of p-type impurities.

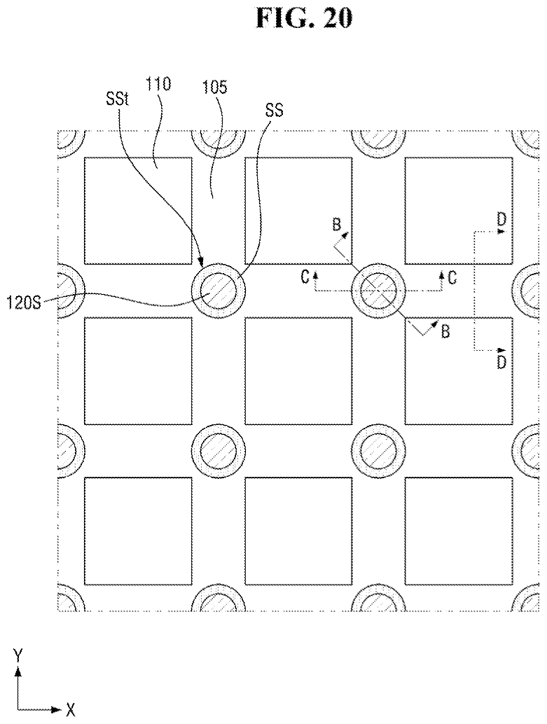

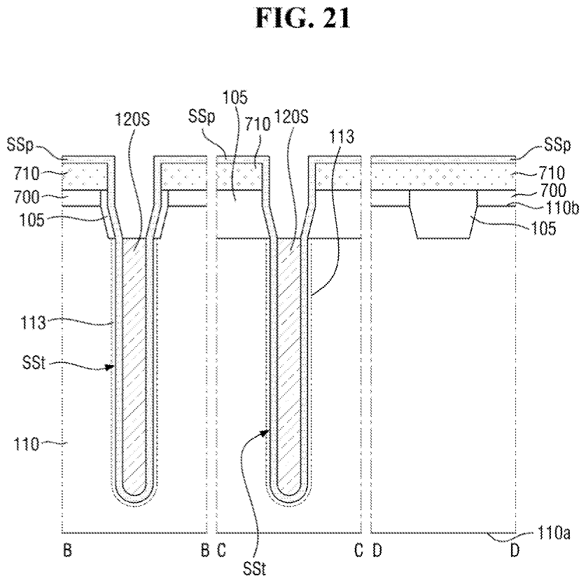

Referring to the exemplary embodiments of FIGS. 20 and 21, a support film SSp and a sacrificial pattern 1205 are formed in the support trench SSt.

The support film SSp may be formed in the support trench SSt. For example, as shown in the exemplary embodiment of FIG. 21, the support film SSp may conformally extend along the profile of the support trench SSt. The support film SSp may include a material having an etching selection ratio with respect to the first substrate 110. For example, the support film SSp may include, but is not limited to, at least one compound selected from silicon oxide, silicon nitride, silicon oxynitride, aluminum oxide, tantalum oxide, and combinations thereof. In some exemplary embodiments, the support film SSp may include silicon oxide.

The sacrificial pattern 120S may be formed on the support film SSp. The sacrificial pattern 1205 may fill at least a partial portion of the support trench SSt. The sacrificial pattern 1205 may include a material haying an etching selection ratio with respect to the support film SSp. For example, in an exemplary embodiment, the sacrificial pattern 1205 may include, but is not limited to, polysilicon poly (Si).

In some exemplary embodiments, the upper portion of the sacrificial pattern 120S may be recessed. Although the exemplary embodiment of FIG. 21 shows the upper surface of the recessed sacrificial pattern 120S as being co-planar (e.g., in the vertical direction) with the lower surface of the first element separation pattern 105, this is merely an example. For example, in other exemplary embodiments, the upper surface of the recessed sacrificial pattern 120S may be higher or lower than lower surface of the first element separation pattern 105.

In some exemplary embodiments, a flattening process may lie performed after forming the sacrificial pattern 1205. For example, a capping film which fills the remaining region of the support trench SSt may be formed on the sacrificial pattern 1205. A flattening process may then be performed on the second surface 110b of the first substrate 110. In some exemplary embodiments, the flattening process may be performed to expose the upper surface of the mask pattern 710. As a result, since a part of the support film SSp extending along the upper surface of the mask pattern 710 is removed, the support structure SS may be formed in the support trench SSt.

Referring to the exemplary embodiments of RIGS. 22 and 23, a pixel separation trench 120t is formed in the first substrate 110 and the sacrificial pattern 120S.

For example, an etching process haying an etching selection ratio with respect to the first substrate 110 and the sacrificial pattern 1205 may be performed. Accordingly, at least partial portions of the first substrate 110 and the sacrificial pattern 120S are removed, and the pixel separation trench 120t may be funned. The pixel separation trenches 120t may be funned in a grid shape from a plan view (e.g., in a plane defined in the first direction X and second direction Y) to define a plurality of unit pixels, such as the first to ninth unit pixels PX1 to PX9. In some exemplary embodiments, the grid point of the pixel separation trench 120t may be formed to correspond to the support trench SSt. In some exemplary embodiments, the etching process of forming the pixel separation trench 120t may be performed on the second surface 110b of the first substrate 110.

In the etching process of forming the pixel separation trenches 120t, the support structure SS may support adjacent unit pixels of the plurality of unit pixels, such as the first to ninth unit pixels PX1 to PX9. As a result, pattern shift due to the leaning phenomenon of the plurality of unit pixels, such as the first to ninth unit pixels PX1 to PX9 may be prevented.

In some exemplary embodiments, as an etching process of forming the pixel separation trench 120t is performed on the second surface 110b of the first substrate 110, a partial portion of the support structure SS adjacent to the second surface 110b of the first substrate 110 may be removed. For example, the thickness of the support structure SS adjacent to the second surface 110b of the first substrate 110 may become less than the thickness of the support structure SS adjacent to the first surface 110a of the first substrate 110.

In some exemplary embodiments, since the pixel separation trenches 120t are formed in a grid shape from a plan view, a portion of the support structure SS that overlaps the pixel separation trench 120t (e.g., in the vertical direction) may be removed. For example, the support structure SS may include a first portion SSa that does not overlap the pixel separation trench 120t formed in a grid shape, and a second portion. SSb that overlaps the pixel separation trench 120t formed in a grid shape. At this time, the height of the second portion SSb of the support structure SS may become less than the height of the first portion SSa of the support structure SS. In such an embodiment, the image sensor described above with respect to the exemplary embodiments of FIGS. 9 and 10 may be fabricated.

Although the removal of a portion of the second portion. SSb of the support structure SS is only shown in FIG. 23, this is merely an example. For example, the second portion SSb of the support structure SS may not be removed, depending on the characteristics of the etching process for forming the pixel separation trench 120t. In such an embodiment, the image sensor described above with respect to the exemplary embodiments of FIGS. 7 and 8 may be fabricated. In other exemplary embodiments, the second portion SSb of the support structure SS may be completely removed depending on, for example, the characteristics of the etching process for forming the pixel separation trench 120t. In such an embodiment, the image sensor described above using the exemplary embodiments of FIGS. 11 and 12 may be fabricated.

While the exemplary embodiment of FIG. 23 shows only a partial portion of the sacrificial pattern 120S remaining after forming the pixel separation trench 120t, this is merely after example. For example, in another exemplary embodiment, the sacrificial pattern 120S may be completely removed after the pixel separation trench 120t is formed.

In some exemplary embodiments, after forming the pixel separation trench 120t, potential harrier layer 113 may be formed in the first substrate 110 exposed by the pixel separation trench 120t. For example, the potential barrier layer 113 may be formed in the first substrate 110 extending along the side surface of the pixel separation trench 120t.

For example, a plasma doping (PLAD) ion implantation process may be performed after forming the pixel separation trench 120t. The potential barrier layer 113 may have a conductivity type that is opposite to the conductivity type of the photoelectric conversion layer PD For example, when the photoelectric conversion layer PD includes n-type impurities, the potential barrier layer 113 may be formed by ion-implantation of the p-type impurities. Accordingly, the potential barrier layer 113 may be formed in the first substrate 110 extending along the side surface of the support trench SSt and the side surface of the pixel separation trench 120t.

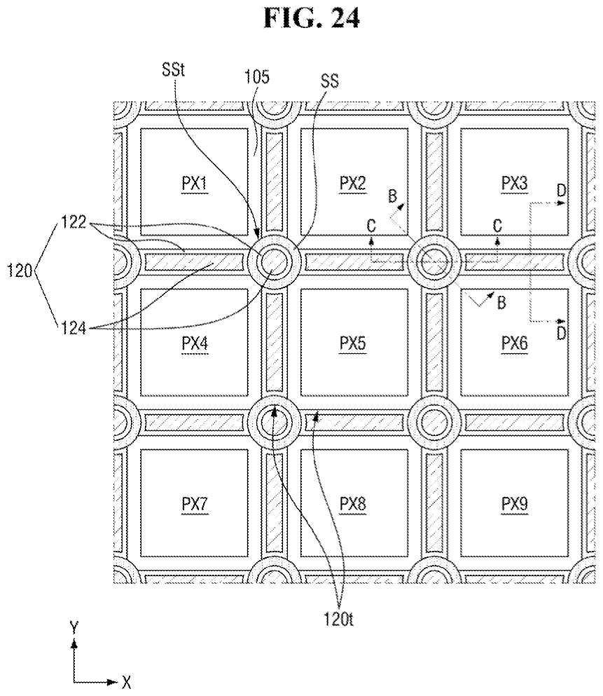

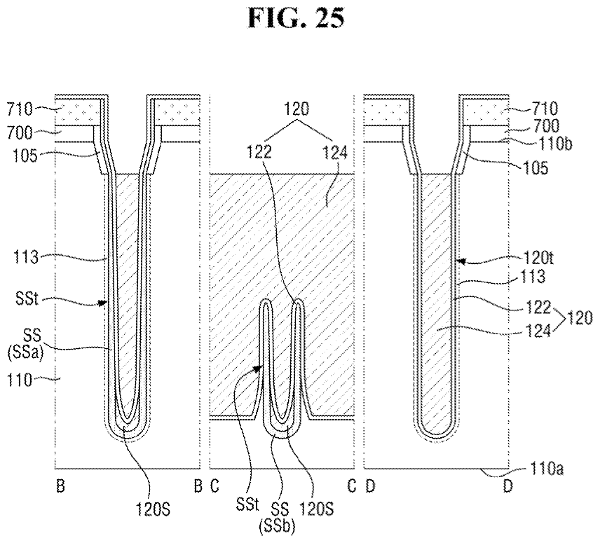

Referring to the exemplary embodiments of FIGS. 24 and 25, a pixel separation pattern 120 is formed in the pixel separation trench 120t.

The pixel separation pattern 120 may be formed to fill at least a partial prion of the pixel separation trench 120t.

In some exemplary embodiments, the pixel separation pattern 120 may include a spacer film 122 and a filling film 124. The spacer film 122 may conformally extend along the side surface of the pixel separation trench 120t. The filling film 124 may be formed on the spacer film 122 to fill at least a partial portion of the pixel separation trench 120t.

In some exemplary embodiments, the spacer film 122 may include an oxide that has a lower refractive index than the first substrate 110. For example, in an exemplary embodiment, the spacer film 122 may include, but is not limited to, at least one compound selected from silicon oxide, aluminum oxide, tantalum oxide, and combinations thereof.

In some exemplary embodiments, the filling film 124 may include a conductive material. For example, the filling film 124 may include, but is not limited to, polysilicon poly (Si).

In some exemplary embodiments, the upper portion of the filling film 124 may be recessed. Although the tapper surface of the recessed filling film 124 in the exemplary embodiment of FIG. 25 is shown as being co-planar (e.g., in the vertical direction) as the lower surface of the first element separation pattern 105, this is merely an example. For example, in other exemplary embodiments, the upper surface of the recessed filling film 124 may be higher or lower than the lower surface of the first element separation pattern 105.

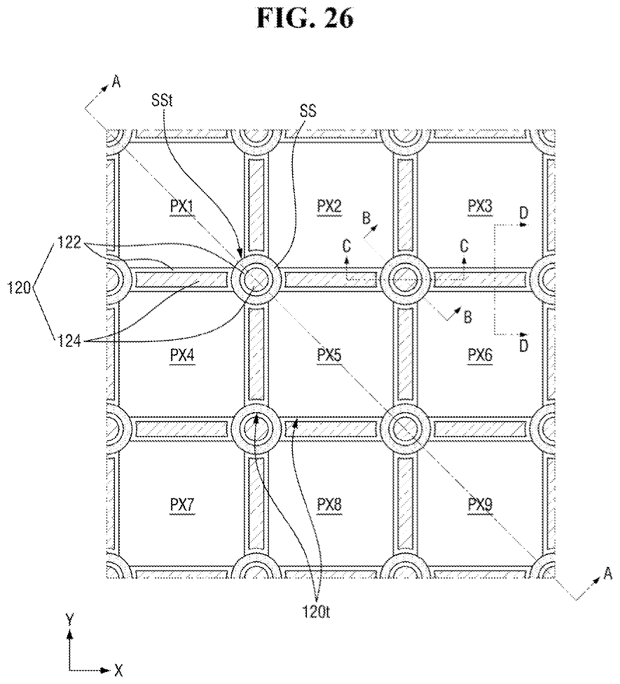

Referring to the exemplary embodiments of FIGS. 26 to 28, a capping pattern 107 is formed in the pixel separation pattern 120.

In some exemplary embodiments, a flattening process may be performed after forming the pixel separation pattern 120. For example, a capping film which fills the remaining region of the pixel separation trench 120t may be formed on the filling film 124. A flattening process of the second surface 110b of the first substrate 110 may then be performed. In some exemplary embodiments, the flattening process may be performed such that the second surface 110b of the first substrate 110 is exposed at the upper surface. As a result, the capping pattern 107 may be formed on the recessed filling film 124. The capping pattern 107 may fill the remaining region of the pixel separation trench 120t. The flattening film 700 and the mask pattern 710 may also be removed.

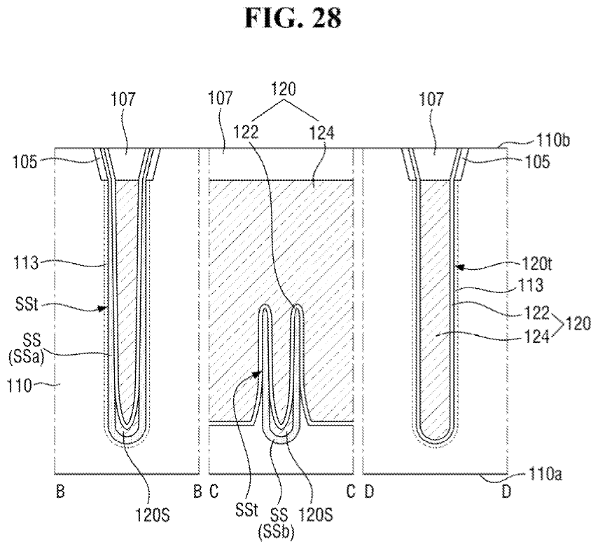

In the exemplary embodiment of FIG. 28, although the depth of the capping pattern 107 is shown as being the same as the depth of the first element separation pattern 105 with respect to the second surface 110b of the first substrate 110, this is merely an example. For example, in other exemplary embodiments, the depth of the capping pattern 107 may be shallower or deeper than the depth of the first element separation pattern 105 with respect to the second surface 110b of the first substrate 110.

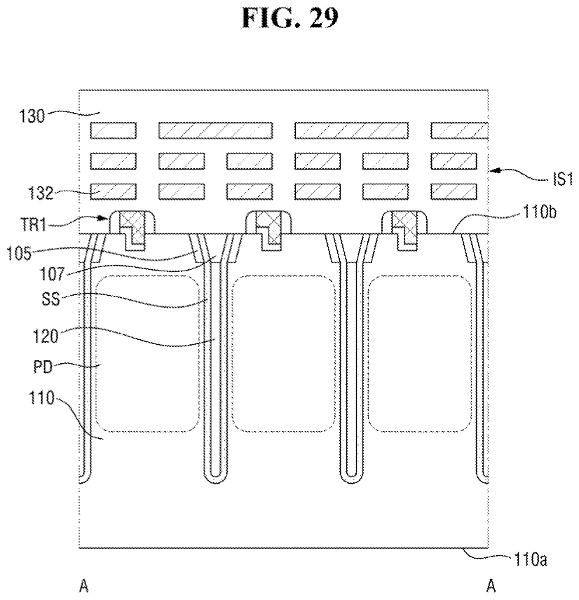

Referring to the exemplar , embodiment of FIG. 29, the first electronic element TR1 and the first wiring structure IS1 are formed on the second surface 110b of the first substrate 110.

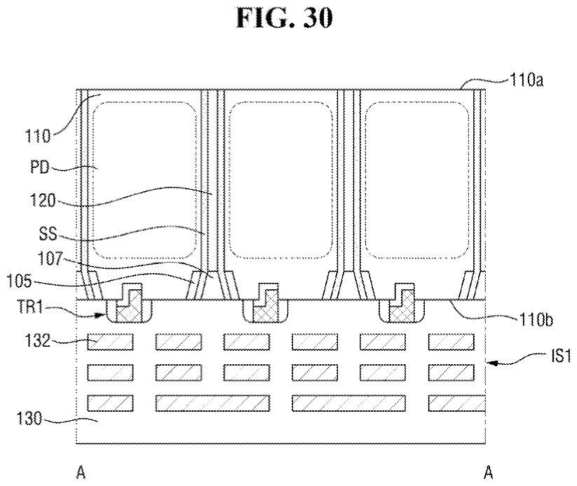

The first electronic element TR1 may be connected to the photoelectric conversion layer PD to form various transistors for processing electric signals. As shown in the exemplary embodiments of FIGS. 29-30, the first wiring structure IS1 may include a first inter-wiring insulation film 130, and a first wiring 112 disposed in the first inter-wiring insulation film 130.

Referring to the exemplary embodiment of FIG. 30, a flattening process of the first surface 110a of the first substrate 110 is performed,

The flattening process may include, for example, but is not limited to, a chemical mechanical polishing (CMP) process.

In some exemplary embodiments, the flattening process of the first surface 110a of the first substrate 110 may be performed to expose the pixel separation trench 120t. Accordingly, a portion of the support structure SS adjacent to the first surface 110a of the first substrate 110 may be removed by the flattening process. The support structure SS may extend from the first surface 110a of the first substrate 110 to the second surface 110b of the first substrate 110.

Referring to the exemplary embodiments of FIGS. 3 to 13, a surface insulation film 140, grid patterns, a first protective film 165, a color filter 170, a microlens 180 and a second protective film 185 are sequentially formed on the first surface 110a of the first substrate 110.

Accordingly, it is possible to provide a method for fabricating an image sensor with increased product reliability and quality.

In concluding the detailed description of exemplary embodiments, those skilled in the art will appreciate that many variations and modifications may be made to the described exemplary embodiments without substantially departing from the principles of the present inventive concepts. Therefore, the disclosed exemplary embodiments of the present inventive concepts are used in a generic and descriptive sense only and not for purposes of limitation.

What is claimed is:

1. An image sensor comprising:
a substrate which includes a plurality of unit pixels, each of the plurality of unit pixels including a photoelectric conversion layer,
a pixel separation pattern disposed in the substrate and having a grid shape that includes a plurality of grid points, the pixel separation pattern is configured to separate each of the plurality of it pixels from each other; and
a support structure disposed in the substrate and positioned to correspond to the plurality of grid points of the pixel separation pattern, the support structure is configured to support adjacent unit pixels of the plurality of unit pixels.

2. The image sensor of claim 1, wherein the support structure is configured connect the adjacent unit pixels of the plurality of unit pixels to each other.

3. The image sensor of claim 1, wherein:
the substrate includes a pixel separation trench that is formed in the grid shape;
the pixel separation pattern is disposed in the pixel separation trench; and
the pixel separation pattern includes a spacer film extending along side surfaces of the pixel separation trench, and a filling film which is disposed on the spacer film and fills at least a partial portion of the pixel separation trench.

4. The image sensor of claim 3, wherein the pacer film extends along a partial portion of side surfaces of the support structure.

5. The image sensor of claim 4, wherein the spacer film is interposed between the support structure and the filling film, and the spacer film is not interposed between the support structure and each of the plurality of unit pixels.

6. The image sensor of claim 3, wherein the filling film includes polysilicon,

7. The image sensor of claim 1, wherein:
the substrate includes a first surface that is configured to receive incident light, and a second surface that is opposite to the first surface, and
the support structure extends from the first surface of the substrate.

8. The image sensor of claim 7, wherein a width of the support structure decreases from the second surface of the substrate towards the first surface of the substrate.

9. The image sensor of claim 7, wherein a thickness of the support structure decreases from the first surface of the substrate towards the second surface of the substrate.

10. The image sensor of claim 1, wherein:
the support structure includes a first portion having an outer surface that directly contacts unit pixels of the plurality of unit pixels, and a second portion having an outer surface that directly contacts the pixel separation pattern; and
a thickness of the second portion of the support structure is less than a thickness of the first portion of the support structure.

11. The image sensor of claim 10, wherein a length of the second portion of the support structure is less than a length of the first portion of the support structure in a vertical direction perpendicular to an upper surface of the substrate.

12. An image sensor comprising:
a substrate that includes a first pixel, a second pixel adjacent to the first pixel in a first direction, and a third pixel adjacent to the first pixel in a second direction intersecting the first direction;
a pixel separation pattern disposed in the substrate and configured to separate the first to third pixels from each other; and
a support structure disposed in the substrate between the second pixel and the third pixel and configured to connect the first to third pixels to each other.

13. The image sensor of claim 12, wherein:
the substrate includes a first surface that is configured to receive incident light, and a second surface that is opposite to the first surface; and
the support structure extends from the first surface of the substrate.

14. The image sensor of claim 13, wherein the support structure is configured to interconnect the first to third pixels adjacent to the first surface of the substrate, and is not configured to interconnect the first to third pixels adjacent to the second surface of the substrate.

15. The image sensor of claim 13, further comprising;
an element separation pattern disposed in the substrate and extending from the second surface of the substrate; and
the support structure penetrates the element separation pattern.

16. The image sensor of claim 12, wherein the support structure includes silk can oxide.

17. The image sensor of claim 12, wherein the support structure has a cylindrical shape.

18. An image sensor comprising:
a first substrate which includes a first surface that is con figured to receive incident light and a second surface that is opposite to the first surface;
a plurality of unit pixels disposed in the first substrate, each of the plurality of unit pixels including a photoelectric conversion layer;
a pixel separation pattern disposed in the first substrate and having a grid shape that includes a plurality of grid points, the pixel separation pattern is configured to separate each of the plurality of unit pixels from each other;
a support structure disposed in the first substrate, the support structure surrounds the plurality of grid points of the pixel separation pattern;
a color filter disposed on the first surface of the first substrate and positioned to correspond to each unit pixel of the plurality of unit pixels;
a microlens disposed on each of the color filters; and
a first wiring structure disposed on the second surface of the first substrate, the first wiring structure including a first inter-wiring insulation film and a first wiring disposed in the first inter-wiring insulation film.

19. The image sensor of claim 18, further comprising:
a second substrate that includes a third surface facing the second surface of the first substrate, and a fourth surface that is opposite to the third surface;
a second wiring structure that includes a second inter-wiring insulation film, and a second wiring disposed in the second inter-wiring insulation film between the second surface and the third surface; and
a connection structure that penetrates the first substrate and the first wiring structure and is connected to the second wiring.

20. The image sensor of claim 19, further comprising:
a first electronic element disposed on the second surface of the first substrate, the first electronic element is connected to the first wiring; and
a second electronic element disposed on the third surface of the second substrate, the second electronic element is connected to the second wiring.
